(19) United States
(12) Patent Application Publication
(10) Pub. No.: US 2026/0255615 A1
(43) Pub. Date: Aug. 27, 2026

(54) MEMORY APPARATUS, SEMICONDUCTOR STRUCTURE AND MANUFACTURING METHOD

(71) Applicant: Yangtze Memory Technologies Co., Ltd., Wuhan (CN)

(72) Inventors: Liangji Zhao, Wuhan (CN); Xu Hou, Wuhan (CN); Bin Liao, Wuhan (CN)

(21) Appl. No.: 19/282,425

(22) Filed: Jul. 28, 2025

(30) Foreign Application Priority Data
Feb. 26, 2025 (CN) 202510220572.9

(51) Int. Cl. H10B 80/00; H01L 23/00; H01L 25/00; H01L 25/065; H01L 25/18; H10B 12/00

(52) U.S. Cl. CPC H10B 80/00; H10B 12/315; H10B 12/50; H10W 90/00; H10W 80/312; H10W 80/327; H10W 90/792

(57) ABSTRACT

A memory apparatus is provided. The memory apparatus may include a first semiconductor structure including a memory cell array and a first bonding layer, the memory cell array including memory banks arranged in two rows along a first direction, and a first region disposed between the two rows of memory banks in a second direction intersecting with the first direction; and a second semiconductor structure including a peripheral circuit and a second bonding layer, the peripheral circuit including a first peripheral region and second peripheral regions, and a circuit of the first peripheral region at least partially different from that of the second peripheral region, wherein the first peripheral region at least partially corresponds to the first region in the third direction, and one of the second peripheral regions at least partially corresponds to one of the memory banks in the third direction.

### CROSS-REFERENCE TO RELATED APPLICATIONS

This application claims the benefit of priority to Chinese Application No. 202510220572.9 filed on Feb. 26, 2025, which is hereby incorporated by reference in its entirety.

### FIELD OF TECHNOLOGY

Implementations of the present disclosure relate to the field of semiconductor technology, and in particular to a memory apparatus, a semiconductor structure, a method of manufacturing the memory apparatus, and a memory system.

### BACKGROUND

Memory devices are memory apparatuses in modern information technology for storing information. Some memory apparatuses, including some non-volatile memory devices and volatile memory devices, gradually become products widely applied in the storage market due to their high storage density, controllable production cost, suitable read/write speed, and retention characteristics. However, as requirements on memory apparatuses continue to increase, there is much room for improvement in memory apparatuses and manufacturing methods thereof.

### SUMMARY

According to one aspect of the present disclosure, a memory apparatus is provided. The memory apparatus may include a first semiconductor structure including a memory cell array and a first bonding layer including first bonding contacts. The memory cell array may include memory banks arranged in two rows along a first direction, and there may be a first region between two rows of the memory banks in a second direction intersecting with the first direction. The memory apparatus may include a second semiconductor structure including a peripheral circuit and a second bonding layer having second bonding contacts. The peripheral circuit may include a first peripheral region and second peripheral regions, and a circuit of the first peripheral region may be at least partially different from that of a second peripheral region of the second peripheral regions. The first bonding layer and the second bonding layer may be bonded in a third direction, and the first bonding contacts and the second bonding contacts may be coupled. The first peripheral region may at least partially correspond to the first region in the third direction, one of the second peripheral regions may at least partially correspond to one of the memory banks in the third direction, and a plane formed by the first direction and the second direction may intersect with the third direction.

In some implementations, the memory apparatus may have two rows of the memory banks. In some implementations, one of the two rows of the memory banks may include the memory banks arranged along the first direction.

In some implementations, the first peripheral region may at least partially overlap the first region in the third direction, and one of the second peripheral regions may at least partially overlap one of the memory banks in the third direction.

In some implementations, the first peripheral region may include at least a first data path circuit configured to transmit at least one of a control instruction, an address signal, or data.

In some implementations, the second peripheral regions may be arranged at an interval in two rows along the first direction, and the two rows of the second peripheral regions may be respectively located on two sides of the first peripheral region in the second direction. In some implementations, a first memory bank of the memory banks may include memory blocks. In some implementations, a second peripheral region corresponding to the first memory bank may include at least a word line driving circuit, a column decoding circuit, and a sensing amplification circuit corresponding to the memory blocks in the first memory bank.

In some implementations, the peripheral circuit may further include a memory bank column control circuit located between the second peripheral region and the first peripheral region. In some implementations, the peripheral circuit may further include a memory bank row control circuit located between two adjacent ones of the second peripheral regions in the first direction.

In some implementations, the first peripheral region may include a first sub-peripheral region located between adjacent ones of the second peripheral regions in the second direction. In some implementations, the first peripheral region may include a second sub-peripheral region located on a side of the first sub-peripheral region in the first direction and located on a side of two rows of the second peripheral regions in the first direction.

In some implementations, the peripheral circuit may include second data path circuits located on two sides of the first data path circuit in the second direction. In some implementations, the second data path circuit may correspond to the memory bank, and a second data path circuit of the second data path circuits may be coupled to the first data path circuit.

In some implementations, the first data path circuit may include a global transmission line and a local transmission line. In some implementations, the second data path circuit may be coupled to the global transmission line through the local transmission line.

In some implementations, the local transmission line may include a control line and a data transmission line. In some implementations, the control line and the data transmission line may be in different interconnection layers in the third direction.

In some implementations, the second semiconductor structure may include interconnection layers stacked in the third direction. In some implementations, the interconnection layers may be located between the peripheral circuit and the second bonding contacts, and the peripheral circuit may be coupled to the second bonding contacts through the interconnection layers.

In some implementations, the interconnection layers in the second semiconductor structure may include a first interconnection layer and a second interconnection layer that are stacked. In some implementations, the first interconnection layer may include first interconnection lines extending in a direction intersecting with the third direction, the second interconnection layer may include second interconnection lines extending in a direction intersecting with the third direction, and an extending direction of the first interconnection lines may intersect with an extending direction of the second interconnection lines. In some implementations, in a direction perpendicular to the third direction, the first interconnection lines may be located between adjacent ones of the second bonding contacts. In some implementations, in a direction perpendicular to the third direction, the second interconnection lines may be located between adjacent ones of the second bonding contacts.

In some implementations, an extension direction of a portion of the first interconnection lines corresponding to the first peripheral region may intersect with an extension direction of a portion of the first interconnection lines corresponding to the second peripheral region. In some implementations, an extending direction of a portion of the second interconnection lines corresponding to the first peripheral region may intersect with an extension direction of a portion of the second interconnection lines corresponding to the second peripheral region.

In some implementations, the memory cell array may include a transistor including a first active region, a second active region, and a gate layer. In some implementations, the memory cell array may include a bit line coupled to the first active region. In some implementations, the memory cell array may include a capacitor structure coupled to the second active region. In some implementations, the peripheral circuit may be coupled to the bit line through the first bonding contact and the second bonding contact, and may be coupled to the gate layer.

According to another aspect of the present disclosure, a semiconductor structure is provided. The semiconductor structure may include a peripheral circuit. The peripheral circuit may include a first peripheral region. The peripheral circuit may include second peripheral regions arranged at an interval in two rows along a first direction. Two rows of the second peripheral regions may be respectively located on two sides of the first peripheral region in a second direction intersecting with the first direction. The first peripheral region may include at least a first data path circuit configured to transmit at least one of a control instruction, an address signal, or data. A second peripheral region of the second peripheral regions may include at least word line driving circuits, column decoding circuits, and sensing amplification circuits.

In some implementations, the semiconductor structure may include a bonding layer having bonding contacts. In some implementations, the bonding contacts may be coupled to at least a portion of a region of the peripheral circuit.

In some implementations, the peripheral circuit may have two rows of the second peripheral regions. In some implementations, one of the two rows of the second peripheral regions may include the second peripheral regions arranged along the first direction.

In some implementations, the peripheral circuit may further include a memory bank column control circuit located between the second peripheral region and the first peripheral region. In some implementations, the peripheral circuit may further include a memory bank row control circuit located between two adjacent ones of the second peripheral regions in the first direction.

In some implementations, the first peripheral region may include a first sub-peripheral region located between adjacent ones of the second peripheral regions in the second direction. In some implementations, at least a portion of the first data path circuit may be located in the first sub-peripheral region. In some implementations, the first peripheral region may include a second sub-peripheral region located on a side of the first sub-peripheral region in the first direction and located on a side of the two rows of the second peripheral regions in the first direction.

In some implementations, the peripheral circuit may include second data path circuits located on two sides of the first data path circuit in the second direction. In some implementations, one of the second data path circuits may correspond to one of the second peripheral regions, and the second data path circuit may be coupled to the first data path circuit.

In some implementations, the first data path circuit may include a global transmission line and a local transmission line. In some implementations, the second data path circuit may be coupled to the global transmission line through the local transmission line.

In some implementations, the local transmission line may include a control line and a data transmission line. In some implementations, the control line and the data transmission line may be in different interconnection layers in a third direction. In some implementations, a plane formed by the first direction and the second direction may intersect with the third direction.

In some implementations, the semiconductor structure may include interconnection layers stacked in the third direction. In some implementations, the interconnection layers may be located between the peripheral circuit and the bonding contacts, and the peripheral circuit may be coupled to the bonding contacts through the interconnection layers.

In some implementations, the interconnection layers in the semiconductor structure may include a first interconnection layer and a second interconnection layer that are stacked. In some implementations, the first interconnection layer may include first interconnection lines extending in a direction intersecting with the third direction, the second interconnection layer may include second interconnection lines extending in a direction intersecting with the third direction, and an extending direction of the first interconnection lines may intersect with an extending direction of the second interconnection lines. In some implementations, in a direction perpendicular to the third direction, the first interconnection lines may be located between adjacent ones of the bonding contacts. In some implementations, in a direction perpendicular to the third direction, the second interconnection lines may be located between adjacent ones of the bonding contacts.

In some implementations, an extension direction of a portion of the first interconnection lines corresponding to the first peripheral region may intersect with an extension direction of a portion of the first interconnection lines corresponding to the second peripheral region. In some implementations, an extending direction of a portion of the second interconnection lines corresponding to the first peripheral region may intersect with an extension direction of a portion of the second interconnection lines corresponding to the second peripheral region.

According to a further aspect of the present disclosure, a method of manufacturing a memory apparatus is provided. The method may include forming a first semiconductor structure. The forming the first semiconductor structure may include forming a memory cell array. The forming the first semiconductor structure may include forming a first bonding layer having first bonding contacts on a side of the memory cell array. The memory cell array may include memory banks arranged in two rows along a first direction, and there may be a first region between two rows of the memory banks in a second direction intersecting with the first direction. The method may include forming a second semiconductor structure. The forming the second semiconductor structure may include forming a peripheral circuit, and forming a second bonding layer having second bonding contacts on a side of the peripheral circuit. The peripheral circuit may include a first peripheral region and second peripheral regions. The method may include bonding the first bonding layer to the second bonding layer so that the first bonding contacts and the second bonding contacts are coupled. The first peripheral region may at least partially correspond to the first region in a third direction, one of the second peripheral regions may at least partially correspond to one of the memory banks in the third direction, and a plane formed by the first direction and the second direction may intersect with the third direction.

In some implementations, forming the peripheral circuit may include forming a first peripheral region by forming at least a first data path circuit in the first peripheral region. In some implementations, the first data path circuit may be configured to transmit at least one of a control instruction, an address signal, or data.

In some implementations, the forming the peripheral circuit may further include forming the second peripheral regions arranged at an interval along the first direction on two sides of the first peripheral region in the second direction. In some implementations, forming the second peripheral regions may include, in a second peripheral region of the second peripheral regions corresponding to a first memory bank, forming at least a word line driving circuit, a column decoding circuit and a sensing amplification circuit corresponding to memory blocks in the first memory bank. In some implementations, the first memory bank may be one of the memory banks.

In some implementations, the forming the peripheral circuit may further include forming a memory bank column control circuit between the second peripheral region and the first peripheral region. In some implementations, the forming the peripheral circuit may further include forming a memory bank row control circuit between two adjacent ones of the second peripheral regions in the first direction.

In some implementations, the first peripheral region may include a first sub-peripheral region located between adjacent ones of the second peripheral regions in the second direction. In some implementations, the first peripheral region may include a second sub-peripheral region located on a side of the first sub-peripheral region in the first direction and located on a side of the two rows of the second peripheral regions in the first direction.

In some implementations, the forming the peripheral circuit may further include forming second data path circuits on two sides of the first data path circuit along the second direction. In some implementations, the second data path circuit may correspond to the memory bank, and the second data path circuit may be coupled to the first data path circuit.

In some implementations, the forming the first data path circuit may include forming a global transmission line and a local transmission line. In some implementations, the second data path circuit is coupled to the global transmission line through the local transmission line.

In some implementations, the forming the local transmission line may include forming a control line and a data transmission line in different layers of the second semiconductor structure.

In some implementations, the forming the second semiconductor structure may further include forming interconnection layers stacked in the third direction. In some implementations, the interconnection layers may be between the peripheral circuit and the second bonding contacts, and the peripheral circuit may be coupled to the second bonding contacts through the interconnection layers.

In some implementations, the interconnection layers in the second semiconductor structure may include a first interconnection layer and a second interconnection layer that are stacked. In some implementations, the first interconnection layer may include first interconnection lines extending in a direction intersecting with the third direction, the second interconnection layer may include second interconnection lines extending in a direction intersecting with the third direction, and an extending direction of the first interconnection lines may intersect with an extending direction of the second interconnection lines. In some implementations, in a direction perpendicular to the third direction, the first interconnection lines may be located between adjacent ones of the second bonding contacts. In some implementations, in a direction perpendicular to the third direction, the second interconnection lines may be located between adjacent ones of the second bonding contacts.

In some implementations, an extension direction of a portion of the first interconnection lines corresponding to the first peripheral region may intersect with an extension direction of a portion of the first interconnection lines corresponding to the second peripheral region. In some implementations, an extending direction of a portion of the second interconnection lines corresponding to the first peripheral region may intersect with an extension direction of a portion of the second interconnection lines corresponding to the second peripheral region.

In some implementations, the forming the memory cell array may include forming a transistor. In some implementations, the forming the transistor may include forming a first active region, a second active region, and a gate layer. In some implementations, the forming the memory cell array may include forming a bit line coupled to the first active region. In some implementations, the forming the memory cell array may include forming a capacitor structure coupled to the second active region. In some implementations, the peripheral circuit may be coupled to the bit line through the first bonding contact and the second bonding contact, and is coupled to the gate layer.

According to a further aspect of the present disclosure, a memory system is provided. The memory system may include one or more memory apparatuses. The one or more memory apparatuses may include a first semiconductor structure including a memory cell array and a first bonding layer including first bonding contacts. The memory cell array may include memory banks arranged in two rows along a first direction, and there may be a first region between two rows of the memory banks in a second direction intersecting with the first direction. The one or more memory apparatuses may include a second semiconductor structure including a peripheral circuit and a second bonding layer having second bonding contacts. The peripheral circuit may include a first peripheral region and second peripheral regions, and a circuit of the first peripheral region may be at least partially different from that of a second peripheral region of the second peripheral regions. The first bonding layer and the second bonding layer may be bonded in a third direction, and the first bonding contacts and the second bonding contacts may be coupled. The first peripheral region may at least partially correspond to the first region in the third direction, one of the second peripheral regions may at least partially correspond to one of the memory banks in the third direction, and a plane formed by the first direction and the second direction may intersects with the third direction. The memory system may include a memory controller coupled to the one or more memory apparatuses and controlling the one or more memory apparatuses.

The implementations of the present disclosure provides a memory apparatus, including a first semiconductor structure and a second semiconductor structure bonded to each other, where a first bonding contact of the first semiconductor structure is coupled with a second bonding contact of the second semiconductor structure to achieve electrical signal interconnection; the first semiconductor structure includes a memory cell array, the memory cell array includes memory banks arranged in two rows along the first direction, and there is a first region between two rows of the memory banks in a second direction intersecting with the first direction; and a peripheral circuit of the second semiconductor structure includes a first peripheral region and second peripheral regions, a circuit of the first peripheral region is at least partially different from that of the second peripheral region, the first peripheral region at least partially corresponds to the first region in the bonding direction, and one of the second peripheral regions at least partially corresponds to the memory bank in the third direction. As compared to the arrangement of more than two rows of memory banks beside the first region, the implementations of the present disclosure dispose two rows of memory banks on the two sides of the first region, and correspondingly dispose two rows of second peripheral regions on the two sides of the first peripheral region, so that the interconnection layers (or interconnection lines) between the first peripheral region and the second peripheral regions can be simplified, the interconnection lines coupled to the second peripheral region at an outer side passing the second peripheral region at an inner side may be reduced, and thus the occupation of the circuit area of the second peripheral region at the inner side is reduced, the interference between the interconnection lines is reduced, and the stability of the memory apparatus is improved.

### BRIEF DESCRIPTION OF THE DRAWINGS

FIG. 1 is a schematic diagram illustrating a memory cell array according to an example implementation;

FIGS. 2 and 3 are schematic diagrams illustrating bonded semiconductor structures according to an implementation of the present disclosure;

FIG. 4 is a schematic diagram illustrating a structure of a memory apparatus according to an implementation of the present disclosure;

FIG. 5 is a schematic diagram illustrating a peripheral circuit of a memory apparatus according to an implementation of the present disclosure;

FIGS. 6 to 16 are schematic diagrams illustrating a layout of a memory apparatus according to an implementation of the present disclosure;

FIG. 17 is a schematic diagram illustrating a semiconductor structure according to an implementation of the present disclosure;

FIG. 18 is a schematic flowchart illustrating a method of a manufacturing semiconductor device according to an implementation of the present disclosure;

FIGS. 19 to 21 are schematic diagrams illustrating a method of manufacturing a semiconductor device according to an implementation of the present disclosure;

FIGS. 22 and 23 are schematic diagrams illustrating an exemplary system according to an implementation of the present disclosure;

FIGS. 24 and 25 are schematic diagrams illustrating another exemplary system according to an implementation of the present disclosure.

### DETAILED DESCRIPTION

Exemplary implementations disclosed in the present disclosure will be described in more detail below with reference to the drawings. Although exemplary implementations of the present disclosure are shown in the drawings, it is to be understood that the present disclosure may be implemented in various forms and should not be limited by the example implementations set forth here. Rather, these implementations are provided so that the present disclosure can be more thoroughly understood and the scope disclosed in the present disclosure can be fully conveyed to those skilled in the art.

It should be appreciated that when an element or layer is referred to as being “on,” “adjacent to,” “connected to,” or “coupled to” other elements or layers, it may be directly on, adjacent to, connected to, or coupled to other elements or layers, or there may be intervening elements or layers. Conversely, when an element or layer is referred to as being “directly on,” “directly adjacent to,” “directly connected to,” or “directly coupled to” other elements or layers, there is no intervening element or layer. Spatial relation terms such as “beneath,” “below,” “lower,” “under,” “above,” “upper,” etc., may be used here for ease of description to describe the relationship between one element or feature and other elements or features shown in the figures. It should be appreciated that in addition to the orientations shown in the figures, the spatial relation terms are intended to also encompass different orientations of an apparatus in use and operation. For example, if the apparatus in the figures is flipped, then an element or feature described as “below” or “under” or “beneath” other elements or features will be oriented “on” other elements or features. Thus, the exemplary terms “below” and “under” may comprise both upper and lower orientations. The apparatus may be additionally oriented (rotated 90 degrees or at other orientations) and the spatial description terminology used here is interpreted accordingly.

A term used here is for the purpose of describing an example implementation only and is not to be considered as limitation of the present disclosure. As used here, the singular forms “a,” “an” and “said/the” are intended to include the plural forms as well, unless the context clearly dictates otherwise. It should also be understood that the terms “consisting of” and/or “comprising,” when used in the present disclosure, identify the presence of stated features, integers, steps, operations, elements and/or components, but do not exclude the presence or addition of one or more other features, integers, steps, operations, elements, components and/or groups. As used here, the term “and/or” includes any and all combinations of the associated listed items.

The memory apparatus provided by the implementations of the present disclosure may include a memory structure and other semiconductor structures, and may be used as a dynamic random access memory (DRAM), or may be used at least as at least a part of a DRAM. The memory apparatus provided by the implementations of the present disclosure may be a memory device or at least a part of a memory device, the memory apparatus may be a DRAM, or at least a part of a memory apparatus in a DRAM, or the memory device includes a DRAM, and the DRAM includes the memory apparatus of the present disclosure, which may be applicable to a double data rate synchronous dynamic random access memory that uses a DDR4 memory specification or a DDR5 memory specification, and a low power consumption double data rate synchronous dynamic random access memory that uses a LPDDR5 memory specification. The examples of the memory apparatus, the semiconductor structure, the semiconductor device, the memory device, and the memory system described in the implementations of the present disclosure are merely illustrative, and are merely a hierarchical logic division with an inclusive relationship to facilitate explanation, and there may be another division manner during an actual implementation, which is not limited in the present disclosure. In some other implementations, for example, a plurality of structures, chips, units, or components may be combined, or may be integrated into another system, or some features may be omitted, or not included.

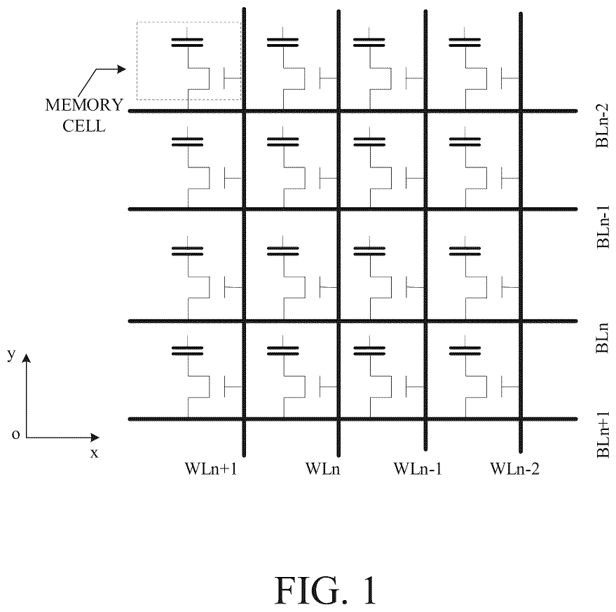

In some implementations, in a DRAM, the memory cells may be arranged as an array in rows and columns such that the memory cells may be addressed by specifying their respective rows and columns of the array. The memory cell array includes a plurality of word lines corresponding to the rows, and a plurality of bit lines corresponding to the columns, where the word lines intersect with the bit lines, and the memory cell on the intersection point of the selected word line and the selected bit line is selected to perform read, write or refresh operation. As illustrated in FIG. 1, the memory cell array 101 may include a plurality of word lines WLn, WLn+1, WLn−1, and WLn−2, and a plurality of bit lines BLn, BLn+1, BLn−1, and BLn−2, where the word lines intersect with the bit lines; and a memory cell in the memory cell array 101 may include a capacitor and a transistor, and one memory cell may include one transistor and one capacitor. The word line may also be a conductive structure such as a gate layer, which serves as a gate of the transistor, a controlled end (source) of the transistor is connected to an electrode of the capacitor, the other controlled end (drain) of the transistor is connected to the bit line, and the other electrode of the capacitor may be grounded or applied with other voltages (such as Vcc/2). As shown in FIG. 1, the memory cell array 101 is arranged as an array of x columns and y rows, the rows and columns may be perpendicular or not perpendicular to each other, the z-direction is the vertical direction or the thickness direction of the device, and the xoy plane intersects with and is perpendicular to the z-direction, where the x-direction may be the first direction in the implementations of the present disclosure, the y-direction may be the second direction in the implementations of the present disclosure, and the z-direction may be the third direction in the implementations of the present disclosure; and the x and y-directions may be interchanged. The extending direction of the word line or row can be parallel to the y-direction or at an angle to the y-direction, the extending direction of the bit line or column may be parallel to the x-direction or at an angle to the x-direction, and an orthographic projection of the word line on the xoy plane is perpendicular to an orthographic projection of the bit line on the xoy plane or is not perpendicular but at a certain angle.

In some implementations, when a read or write operation is performed, a word line select signal may be used to select a corresponding word line, a corresponding bit line may be selected according to a column select signal, and the word line and the bit line may be simultaneously selected to locate the selected memory cell, where the transistor of the selected memory cell is turned on due to the operating voltage applied to the word line, so that the read, write or refresh operation may be performed on the selected memory cell. In some implementations, the capacitor may be replaced with another memory structure, including but not limited to: a phase change memory structure, a resistive change memory structure, a magnetic change memory structure, or the like.

In some implementations, logical 1 and 0 are represented respectively by the amount of charge stored in the capacitor, e.g., the high and low voltage difference between the two ends of the capacitor. The voltage signal on the word line is applied to the gate to control the turn-on or turn-off of the transistor, thereby enabling the selection and non-selection of the capacitor, and then the data information stored in the capacitor is read through the bit line, or the data is written into the capacitor through the bit line for storage.

In some implementations, the DRAM memory apparatus or DRAM memory device further includes a peripheral circuit connected to the memory cell array of FIG. 1. For example, the peripheral circuit may include, but is not limited to, a sensing amplification circuit, a row decoding circuit, a column decoding circuit, a voltage generation circuit, or the like. The sensing amplification circuit is connected with the bit line, the sensing amplification circuit may be configured to capture weak voltage fluctuation on the bit line, and determine the capacitance voltage of the memory cell locally from the voltage fluctuation, and the sensing amplification circuit can include a latch for latching the determined capacitance voltage value, so that the information stored in the memory cell is transferred from the capacitor to the sensing amplification circuit. The sensing amplification circuit may include a differential sensing amplification circuit connected with two bit lines, which uses a selected bit line and a complementary bit line as a reference line to detect and amplify a voltage difference between a pair of bit lines. The row decoding circuit may be configured to address a row of the memory cell array and apply an operating voltage to the word line. The column decoding circuit may be configured to address a column of the memory cell array, and apply a bit line voltage, or receive a bit line voltage. The voltage generation circuit may generate a desired high and low voltage for each device.

In some implementations, the peripheral circuit may include a complementary metal-oxide-semiconductor (CMOS) structure or a CMOS circuit, including a digital or analog circuit composed of transistors, and the peripheral circuit may be configured to control the memory cell array or supply power to the memory cell array. Improvement of the device integration level of the peripheral circuit may facilitate improving the overall integration level of the memory apparatus, and improvement of the device stability of the peripheral circuit may facilitate improving the operating stability of the memory apparatus.

In some implementations, the peripheral circuit and the memory cell array may be disposed in the same semiconductor structure or the same wafer. In some implementations, the peripheral circuit and the memory cell array may be respectively located in different wafers, and the peripheral circuit and the memory cell array are fixed and coupled by bonding to form a memory apparatus.

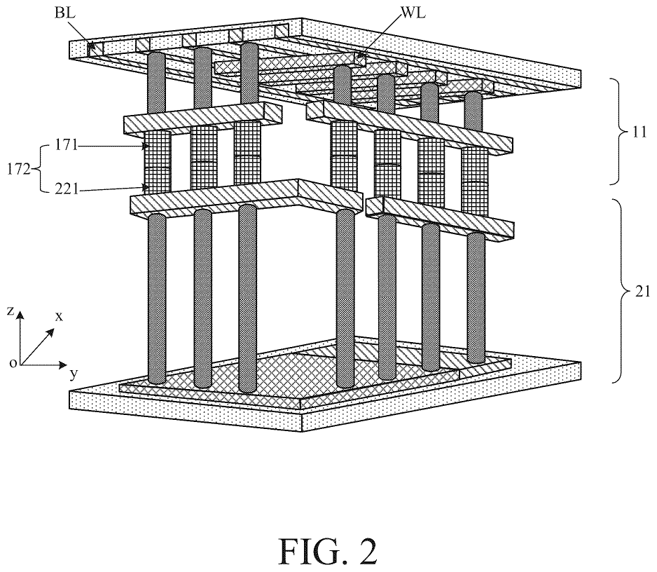

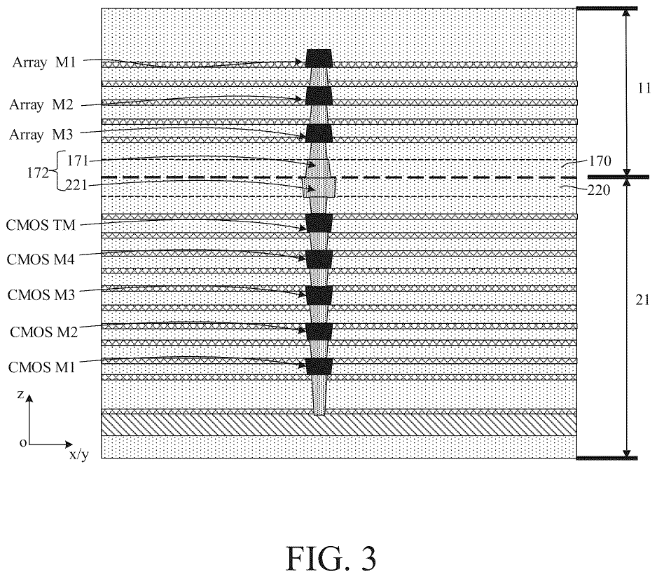

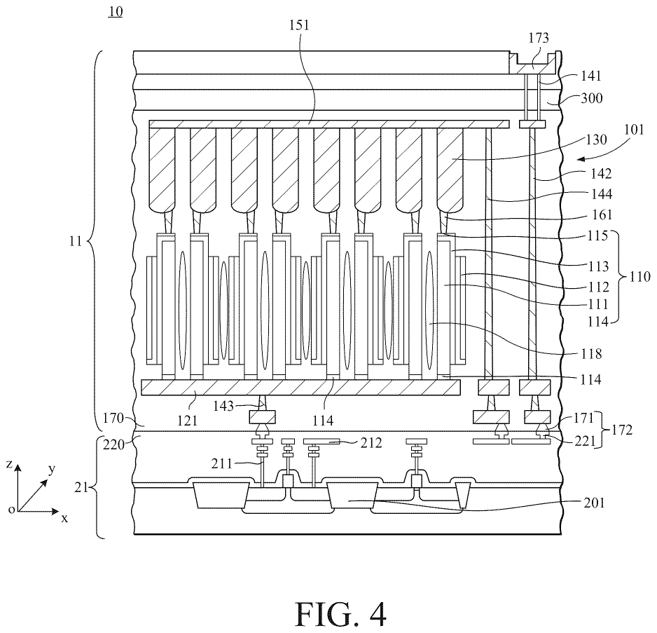

In some implementations, FIG. 2 illustrates a schematic diagram of the bonded first semiconductor structure 11 and second semiconductor structure 21. FIG. 2 illustrates a schematic diagram only showing that the first semiconductor structure 11 and the second semiconductor structure 21 are bonded through the first bonding contacts 171 and the second bonding contacts 221. The semiconductor structure may be, e.g., in the form of wafer. The word line and the bit line are shown in FIG. 2 by way of example. For the memory cell array 101, the structure of the peripheral circuit is not limited in FIG. 2. A reference may be made to FIG. 1 for the arrangement of the memory cell array 101, the word lines and the bit lines, example bonding layer and example circuit layer are shown in FIG. 3, and a reference may be made to FIG. 4 for an example memory cell array 101 and an example peripheral circuit.

The first semiconductor structure 11 may include a DRAM memory cell array 101, and a memory cell may include a transistor and a capacitor, where a gate of the transistor is coupled to the word line, or a gate layer extending along the y-direction or the x-direction is disposed, the gate layer serves as a word line, and corresponds to channels of the transistors; a source or a drain of the transistor is coupled to the bit line, one of the source and the drain of the transistor that is not coupled to the bit line is coupled to an electrode of the capacitor, and the other electrode of the capacitor may be grounded or applied with another voltage (such as Vcc/2); and the bit line and the word line intersect in the xoy plane, and a word line and a bit line may be simultaneously selected to locate and select one memory cell on the intersection point.

The second semiconductor structure 21 may include a peripheral circuit, which may include, but is not limited to, a sensing amplification circuit, a row decoding circuit, a column decoding circuit, a voltage generation circuit, or other digital or analog circuits, and the peripheral circuit may include, but is not limited to, transistors and other devices. The second semiconductor structure 21 may control the operation of the first semiconductor structure 11, provide different voltages to different devices in the first semiconductor structure 11, and provide different voltages according to different timings.

Before the first semiconductor structure 11 and the second semiconductor structure 21 are bonded, the to-be-bonded surfaces of the first semiconductor structure 11 and the second semiconductor structure 21 respectively have a first bonding layer 170 of a plurality of first bonding contacts 171 and a second bonding layer 220 of a plurality of second bonding contacts 221. The first bonding contacts 171 and the second bonding contacts 221 respectively lead the electrical signal of the semiconductor structures to the to-be-bonded surface, and the bonding contacts may include structures such as bonding pads, conductive plugs or the like. The to-be-bonded surfaces or the to-be-bonded layers of the first semiconductor structure 11 and the second semiconductor structure 21 are bonded, and the surfaces of the two to-be-bonded layers contact to form a bonding interface.

The first bonding layer 170 and the second bonding layer 220 are contacted and bonded with each other at the bonding interface to achieve the bonding and fixing of the first semiconductor structure 11 and the second semiconductor structure 21, where a larger bonding area may provide a larger bonding force, a physical boundary may not exist between the first bonding layer 170 and the second bonding layer 220 after the bonding, and the first bonding layer 170 and the second bonding layer 220 may be considered as a bonding interface.

A physical boundary may not exist between the first bonding contact 171 and the second bonding contact 221 after the bonding, and the first bonding contact 171 and the second bonding contact 221 may be considered as a bonding contact 172.

The bonding contact 172 penetrates through the bonding interface, and the bonding interface is formed after two dielectric layers or two to-be-bonded layers are contacted and bonded with each other.

A part of the bonding contact 172 located in the first semiconductor structure 11 is the first bonding contact 171 before the bonding, and a part of the bonding contact 172 located in the second semiconductor structure 21 is the second bonding contact 221 before the bonding.

The bonding contacts 172 may lead the electrical signals of the first semiconductor structure 11 and the second semiconductor structure 21 to the bonding interface for electrical signal interconnection.

The bonding contacts may be connected to each part of the semiconductor structures through a conductive structure such as a wiring layer, a connection structure, a contact structure or the like.

In some implementations, referring to FIG. 3, the first bonding layer 170 is located on a side surface of the first semiconductor structure 11 in the negative z-direction, the first bonding layer 170 includes a first dielectric layer, and the plurality of first bonding contacts 171 penetrate through the first dielectric layer to be coupled to the interconnection layer in the first semiconductor structure 11 to lead out electrical signals of the device structures such as word lines and bit lines.

It can be understood that, in each of the first semiconductor structure 11 and the second semiconductor structure 21, there are a plurality of interconnection layers that are stacked and coupled to each other and conductive plugs, so as to lead out electrical signals of the device structures located at different layer heights.

FIG. 3 is merely an example, the first semiconductor structure 11 (or an array wafer) has a plurality of interconnection layers Array M1 to Array M3 sequentially stacked along the negative z-direction and connected by a conductive plug therebetween, and the Array M3 is closest to the bonding contacts. The second semiconductor structure 21 (or a CMOS wafer) has a plurality of interconnection layers CMOS M1 to CMOS M4 and CMOS TM sequentially stacked along the positive z-direction, and the CMOS TM is closest to the bonding contacts. The number of interconnection layers in FIG. 3 is only an example, and more interconnection layers may also be disposed, and the number of interconnection layers is not limited.

In some implementations, the interconnection lines within adjacent interconnection layers in FIG. 3 may transmit different signals, including control signals, read/write data.

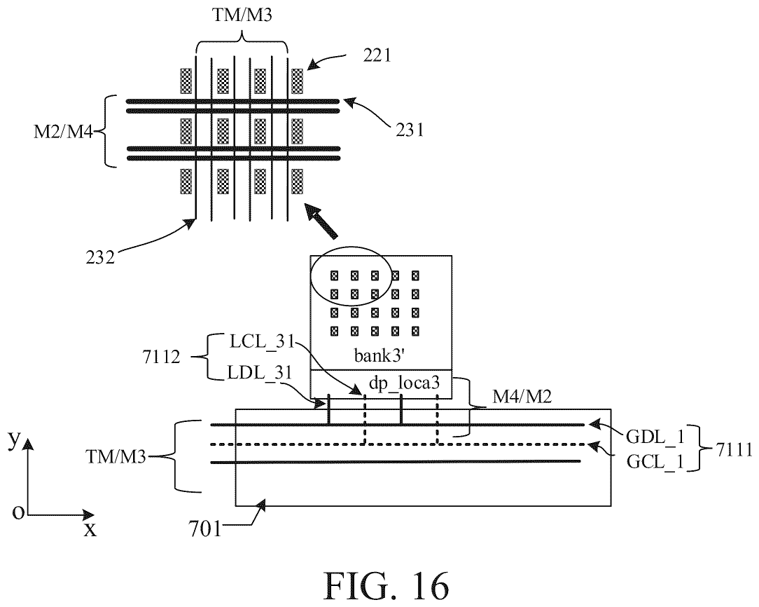

As described below in conjunction with the FIG. 16, some of the interconnection lines of the CMOS TM of FIG. 3 extending along the x-direction may serve as global control lines GCL_1 to transmit global control signals; some of the interconnection lines of the CMOS M4 extending along the y-direction may serve as local control lines LCL_31 to transmit local control signals; and LCL_31 may be coupled to GCL_1 through a conductive plug extending along the z-direction.

Some of the interconnection lines of the CMOS M3 extending along the x-direction may serve as global data transmission lines GDL_1 to transmit global data; some of the interconnection lines of the CMOS M2 extending along the y-direction may serve as local data transmission lines LDL_31 to transmit local data; and LDL_31 may be coupled to GDL_1 through a conductive plug extending along the z-direction. In the CMOS TM to CMOS M1. Each of the interconnection layers may have an interconnection line that transmits a power supply, or the power supply line is located in a higher interconnection layer such as a CMOS TM, or a CMOS M4.

In some implementations, the same interconnection layer may have multiple interconnection lines, different regions or interconnection lines connecting different devices may receive different levels, voltages, or transmit different signals and data, and different interconnection lines may have different widths, and may have different extending directions.

The extending directions of interconnection lines in the different interconnection layers as illustrated in FIG. 3 may not be identical, and the extending directions of interconnection lines in adjacent interconnection layers may intersect or may be perpendicular. For example, some interconnection lines in the CMOS TM may extend along the y-direction, and some interconnection lines in CMOS M4 adjacent to and below the CMOS TM may extend along the x-direction; or some interconnection lines in the CMOS TM may extend along the x-direction, and some interconnection lines in the CMOS M4 may extend along the y-direction.

In conjunction with the FIG. 16 below, the first interconnection line 231 of the CMOS M2 or the CMOS M4 is located between the adjacent second bonding contacts 221, and the second interconnection line 232 of the CMOS M3 or the CMOS TM is located between the adjacent second bonding contacts 221.

At least a portion of some of the first interconnection lines 231, such as LCL_31 or LDL_31, are located at the first peripheral region 701; and LCL_31 and LDL_31 may intersect with or be perpendicular to the first interconnection lines 231 in the memory cell array. Some of the second interconnection lines 232, such as GCL_1 or GDL_1, are located at the first peripheral region 701, and GCL_1 and GDL_1 may intersect with or be perpendicular to the second interconnection line 232 in the memory cell array.

For example, the word line, the bit line, the first bonding contact 171, the second bonding contact 221, and the interconnection layer may include a conductive material such as copper, tungsten, gold, silver, titanium, nickel, or the like. The first dielectric layer and the second dielectric layer may include an insulating material such as silicon oxide, silicon nitride, silicon oxynitride, aluminum oxide, or the like. The first dielectric layer and the second dielectric layer may electrically isolate the bonding contacts, and may provide a better plane for the bonding surface, provide a larger bonding area, and improve bonding adhesion.

In some implementations, the first semiconductor structure 11 shown in FIG. 2 may include a memory cell array 101, which may include, but is not limited to, a DRAM, a phase change memory structure, a resistive change memory structure, or a magnetic change memory structure. Taking DRAM as an example, as shown in FIG. 4, the first semiconductor structure 11 may include at least a transistor 110 and a capacitor structure 130 coupled to the transistor 110, and the capacitor structure 130 in FIG. 4 may be replaced with a phase change memory structure, a resistive change memory structure, and a magnetic change memory structure to form other memory apparatuses 10. The specific structure of the transistor 110 and the capacitor structure 130 may not be limited. The transistor 110 may include a planar transistor and a vertical transistor extending along the z-direction, or may have other forms; and the capacitor structure 130 may include a first electrode, a dielectric layer, and a second electrode, where the dielectric layer electrically isolates the first electrode and the second electrode, and one electrode of the capacitor structure 130 may extend along the z-direction, and may have a pillar shape.

In some implementations, referring to the memory apparatus 10 illustrated in FIG. 4, the memory apparatus 10 includes a first semiconductor structure 11 and a second semiconductor structure 21 which are bonded in a z-direction; the first semiconductor structure 11 has a first bonding layer 170 including a plurality of first bonding contacts 171, and the second semiconductor structure 21 has a second bonding layer 220 including a plurality of second bonding contacts 221; and the first bonding layer 170 and the second bonding layer 220 are bonded in the z-direction, and the first bonding contacts 171 and the second bonding contacts 221 are coupled to achieve electrical signal interconnection of the two semiconductor structures, which may include, but are not limited to, power supply, data transmission, and control signal communication interconnections.

The memory cell array 101 of the first semiconductor structure 11 includes a plurality of semiconductor bodies 111 extending along the z-direction, and a first active region 114 and a second active region 115 located at two opposite ends of the semiconductor body 111 in the z-direction, for example, respectively located at the bottom and the top of the semiconductor body 111; the two ends of the semiconductor body 111 may be doped to form the first active region 114 and the second active region 115, which are used respectively as the source and the drain of the transistor 110, where the positions of the source and the drain are interchangeable; the region of the semiconductor body 111 between the first active region 114 and the second active region 115 serves as the channel region of the transistor 110; and the channel region may have a doping type opposite to the doping type of the first active region 114. The first active region 114, the channel region of the semiconductor body 111, and the second active region 115 may not have physical boundaries.

For example, the cross-sectional shape of the semiconductor body 111 in the xoy plane may include, but is not limited to, a rectangle, a quadrangle, another polygon, a circle, an ellipse, or other irregular shapes, which is not limited in the present disclosure.

The semiconductor body 111 may include, but is not limited to, an elementary semiconductor material (e.g., silicon, germanium, etc.), a III-V compound semiconductor material, a II-VI compound semiconductor material, an organic semiconductor material, or other semiconductor materials known in the art. For example, the semiconductor body 111 may include silicon, germanium, silicon carbide, or the like. For example, The semiconductor body 111 may also include a material such as indium gallium zinc oxide (IGZO), or the like, where the IGZO may include an oxide of elements such as indium, gallium and zinc, or the like, and has excellent semiconductor characteristics. The addition of indium and gallium may increase the electron mobility of the semiconductor material, which may achieve a lower operating voltage and lower power consumption compared to conventional semiconductor materials such as silicon; and the addition of zinc helps to improve the stability of the semiconductor material. The IGZO material can make the semiconductor body 111 be in direct contact with the metal material of the bit line 121, the capacitor structure 130 or other contact structures to reduce the contact resistance.

The memory cell array 101 further includes a gate layer 112 extending along the y-direction, where the gate layer 112 covers a portion (a middle region) of a region of a sidewall of the semiconductor body 111 extending along the z-direction, and the gate layer 112 may cover a sidewall of the semiconductor body 111 between the first active region 114 and the second active region 115, for example, may cover a channel region of the semiconductor body 111; and the gate layer 112 serves as a control gate of the transistor 110 to control turn-on and turn-off of the transistor 110. The gate layer 112 may serve as a word line corresponding to a plurality of semiconductor bodies 111 arranged along the y-direction, with one transistor 110 including a portion of the gate layer 112 overlapping the semiconductor body 111 to which it belongs; and the transistor 110 further includes a gate dielectric layer 113 between the semiconductor body 111 and the gate layer 112, and the gate dielectric layer 113 may extend along the y-direction and at least cover a channel region of the semiconductor body 111.

The gate layer 112 may include a single-layer conductive structure or a multi-layer material structure. For example, the gate layer 112 may include a conductive layer away from the semiconductor body 111, and a connection layer between the conductive layer and the semiconductor body 111. The connection layer may include, but is not limited to, a metal silicide or a high dielectric material to increase the adhesion between the gate layer 112 and the gate dielectric layer 113, and may include, but is not limited to, titanium nitride, tantalum nitride, or the like. The conductive layer of the gate layer 112 may include, but is not limited to, a conductive material such as tungsten, aluminum, copper, cobalt, gold, silver, platinum, titanium, nickel, or the like.

For example, one semiconductor body 111, a portion of the gate layer 112 overlapping the semiconductor body 111 in the x-direction, and a portion of the gate dielectric layer 113 overlapping the semiconductor body 111 in the x-direction may constitute one transistor 110; a dielectric material may be filled between adjacent transistors 110, and the dielectric material may include or enclose an air gap 118 to reduce the inductive capacitance; and a conductive structure extending along the y-direction may be disposed between adjacent semiconductor bodies 111 to reduce crosstalk between adjacent transistors 110. The air gap 118 may include, but is not limited to, a chamber, a trench, or the like. The conductive structure and the gate layer 112 may be disposed on two opposite sides of one semiconductor body 111 in the x-direction, and when the gate layer 112 is applied with the turn-on voltage of the transistor 110, the conductive structure may be grounded or connected to a fixed voltage (e.g., a negative voltage) to reduce crosstalk between the transistors 110; and the fixed voltage may be a fixed voltage value calibrated during the factory testing phase of the memory apparatus 10, or may have a calibrated voltage interval. The conductive structure may include a single-layer conductive structure, or may include a multi-layer material structure.

As illustrated in FIG. 4, two gate layers 112 disposed face-to-face are disposed between two adjacent semiconductor bodies 111, where an air gap 118 is disposed between the two gate layers 112 disposed face-to-face, and an air gap 118 is also disposed between the sides of the semiconductor body 111 at which the gate layer 112 is not disposed, or a conductive structure may be disposed between the sides of the semiconductor body 111 at which the gate layer 112 is not disposed. In other implementations, in order to increase a control performance of the gate structure of the semiconductor body 111, two gate layers 112, or an all-around gate layer 112 surrounding the sidewall of the semiconductor body 111 may be provided for one semiconductor body 111. In order to accommodate the improvement of the integration level of the semiconductor device and the reduction of the parasitic capacitance and the parasitic resistance, the conductive structure may also have other arrangements. For example, one semiconductor body 111 may correspond to one conductive structure.

In some implementations, referring to FIG. 4, a bottom portion (the first active region 114) of the semiconductor body 111 may extend beyond the gate dielectric layer 113 and the gate layer 112 along the z-direction. A top portion (the second active region 115) of the semiconductor body 111 extends beyond the gate layer 112 along the z-direction to be flush with an upper portion of the gate dielectric layer 113, and an upper surface of the second active region 115 of the semiconductor body 111 is exposed by the gate dielectric layer 113 to facilitate coupling with the capacitor structure 130 or other contact structures; and a portion of the gate dielectric layer 113 may surround the top region of the semiconductor body 111 along the lateral direction perpendicular to the z-direction to reduce a leakage current. The gate dielectric layer 113 and the dielectric material filled between the transistors 110 or the insulating materials for other portions may have the same or similar material, and there may not be a physical boundary between the gate dielectric layer 113 and the dielectric material of the portions when the gate dielectric layer 113 is in contact with the dielectric material of the portions.

In some implementations, the memory cell array 101 further includes a bit line 121 extending along the x-direction, and the bit line 121 is disposed on a side close to the first active region 114 of the semiconductor body 111 and coupled to the first active regions 114 of the plurality of semiconductor bodies 111. An end of the semiconductor body 111 having the first active region 114 may be heavily doped or a metal silicide may be formed on the end of the semiconductor body 111 having the first active region 114 to reduce the contact resistance between the semiconductor body 111 and the bit line 121, and the bit line 121 may include a metal conductive material or a metal-semiconductor compound; for example, the semiconductor body 111 may include silicon, and the bit line 121 may include a metal silicide, such as tungsten silicide, titanium silicide, or tantalum silicide; or a metal silicide layer may be included, and a metal layer is deposited on a side of the metal silicide layer away from the semiconductor body 111 to form the bit line 121, where the metal layer may include, but is not limited to, tungsten, copper, aluminum, or the like.

In some implementations, the semiconductor body 111 may be formed by etching a semiconductor layer (or a semiconductor substrate, or a semiconductor layer on a semiconductor). For example, a trench is formed, which extends along the x-direction and the y-direction and penetrates through the semiconductor layer, and the trench divides the semiconductor layer into the semiconductor bodies 111; or the trench may not penetrate through the semiconductor layer, and the semiconductor layer is thinned from the back side thereof so that the trench is exposed to penetrate through the semiconductor layer, where in the x-direction and the y-direction, the bottom portions of respective adjacent semiconductor bodies 111 are spaced apart, and are not connected by the semiconductor material.

In some other implementations, a trench extending along the x-direction penetrates through the semiconductor layer, and a trench extending along the y-direction does not penetrate through the semiconductor layer, where the remaining semiconductor material forms semiconductor strips extending along the x-direction and spaced apart from each other, the semiconductor body 111 is located above and connected to the semiconductor strip, and there is no physical boundary between the semiconductor body 111 and the semiconductor strip; and the adjacent semiconductor bodies 111 along the y-direction are spaced apart from each other and are not connected by the semiconductor material, and the bottom portions of the adjacent semiconductor bodies 111 along the x-direction are connected by the semiconductor strip. The bit line 121 may be formed based on the semiconductor strip. For example, the semiconductor strip may be heavily doped to form the bit line 121; or a metallization process is performed on the semiconductor strip to form a metal silicide so as to form the bit line 121; or a metal may be deposited on the metal silicide to form the bit line 121; or a metal may be deposited directly to form the bit line 121.

In some implementations, the memory cell array 101 in FIG. 4 further includes a capacitor structure 130, which may be located above the semiconductor body 111 and coupled to the second active region 115 of the semiconductor body 111. For example, one electrode of the capacitor structure 130 is coupled to the second active region 115 of the semiconductor body 111, and the other electrode is connected to the common voltage or ground. The gate layer 112 serves as a word line, and one gate layer 112 may correspond to a plurality of semiconductor bodies 111 arranged in the y-direction; and one bit line 121 may correspond to a plurality of semiconductor bodies 111 arranged in the x-direction. When the gate layer 112 and the bit line 121 are selected, the semiconductor body 111 corresponding to both the gate layer 112 and the bit line 121 is selected; in this way, the semiconductor body 111 is turned on to select the corresponding capacitor structure 130, for charging and discharging the capacitor structure 130, or sensing the amount of the charges to perform operations such as write, refresh, read, or the like.

In some implementations, the capacitor structure 130 may include a first electrode extending along the z-direction, a dielectric layer surrounding the first electrode, and a second electrode surrounding the dielectric layer, where the dielectric layer is located between the first electrode and the second electrode, and the second electrode is coupled to an end of the semiconductor body 111 away from the bit line 121; that is, the second electrode is coupled to the second active region 115 of the semiconductor body 111.

The size in the x-direction of one end of the capacitor structure 130 away from the semiconductor body 111 in the z-direction may be greater than or equal to the size in the x-direction of one end of the capacitor structure 130 close to the semiconductor body 111 in the z-direction.

The first electrodes of the plurality of capacitor structures 130 may be connected to an interconnection layer (e.g., the interconnection layer 151 illustrated in FIG. 4) to be connected to a common voltage or ground.

Alternatively, the plurality of capacitor structures 130 may share a first electrode, where one end of the first electrode away from the semiconductor body 111 has a layer structure extending along the x/y-direction, the first electrode is grounded or connected to other operating voltages through the interconnection layer 151, and the plurality of capacitor structures 130 share the first electrode and are connected to the common voltage.

In some implementations, referring to FIG. 4, a contact portion 161 may be disposed between the capacitor structure 130 and the semiconductor body 111, and the semiconductor body 111 is coupled to the capacitor structure 130 through the contact portion 161, so as to reduce the contact resistance and optimize the electrical connection performance.

For example, the contact portion 161 may include a metal silicide to reduce the contact resistance between the semiconductor body 111 and the capacitor structure 130 and improve the adhesion. For example, the contact portion 161 may include a material such as titanium silicide, tantalum silicide, tungsten silicide, or the like.

The contact portion 161 may include a single-layer structure or a multi-layer structure, where a portion of the contact portion 161 close to the semiconductor body 111 and in contact with the semiconductor body 111 may include a metal silicide to reduce the contact resistance and improve the adhesion; and a portion of the contact portion 161 away from the semiconductor body 111 and in contact with the capacitor structure 130 may include metal to improve an electrical connection performance.

For example, the gate layer 112, the first electrode, and the second electrode may include, but are not limited to, conductive materials such as tungsten, gold, silver, platinum, copper, aluminum, titanium, chromium, cobalt, nickel, tungsten nitride, titanium nitride, tantalum nitride, or the like.

In addition to the conductive materials above, the bit line 121 may include a doped semiconductor material, such as doped silicon, or the like, or may include a metal silicide.

The gate dielectric layer 113 and the dielectric layer in the capacitor structure 130 may include, but are not limited to, an insulating material such as silicon oxide, silicon nitride, silicon oxynitride, or the like, or may further include a high-k dielectric material such as aluminum oxide, or the like.

In some implementations, the first semiconductor structure 11 or the memory apparatus 10 may include a first connection structure 141 located on a side of the capacitor structure 130 away from the transistor 110, and a pad 173 located on the first connection structure, where the pad 173 is coupled to the first connection structure 141, and the pad 173 and the first connection structure 141 form a lead-out structure.

The first connection structure 141 may extend through the semiconductor layer 300 along the z-direction to couple to the second connection structure 142 under the first connection structure 141, and the semiconductor layer 300 may include a semiconductor substrate.

The first connection structure 141 may include a conductive plug, a conductive pillar, a conductive strip, or a through silicon via (TSV).

The lead-out structure may further include other interconnection layers located on a side of the capacitor structure 130 away from the transistor 110, where the interconnection layer is located in the semiconductor layer or on the semiconductor layer, and may include, but is not limited to, a redistribution layer. The pad 173 may be disposed in a dielectric material on the semiconductor layer to reduce a leakage.

The second connection structure 142 extends along the z-direction to couple to the first connection structure 141 and to the bonding contact 172 (or the first bonding contact 171), and the second connection structure 142 is further coupled to the peripheral circuit 201 through the bonding contact 172 and the interconnection layer and the connection structure in the second semiconductor structure 21 to achieve the electrical signal interconnection. The pad 173 as an I/O interface of the memory apparatus 10 provides power to the memory apparatus 10 and makes an external communication interaction.

In some implementations, the semiconductor layer 300 may belong to a substrate portion of the first semiconductor structure 11 or a layer on the substrate, or the semiconductor layer 300 does not belong to a portion of the first semiconductor structure 11. The bit line 121 is formed on the back side of the substrate of the first semiconductor structure 11, or relatively close to the back side of the substrate of the first semiconductor structure 11; and the capacitor structure 130 is formed on the front side of the substrate, or relatively close to the front side of the substrate.

In some implementations, the first semiconductor structure 11 further includes at least a third connection structure 143 located between the bit line 121 and the bonding contact (the first bonding contact 171), and the bit line 121 is coupled to the bonding contact through the third connection structure 143 to lead the electrical signal to the bonding interface to be interconnected with the peripheral circuit 201.

The first semiconductor structure 11 further includes a fourth connection structure 144, and the interconnection layer 151 is coupled to the bonding contact through the fourth connection structure 144 to lead the electrical signal to the bonding interface to be interconnected with the peripheral circuit 201.

The first semiconductor structure 11 may further include other connection structures to couple the gate layers 112 and the bonding contacts.

For example, a connection structure is disposed on at least one end of the first semiconductor structure 11 in the y-direction to lead the electrical signal of the gate layers 112 to the bonding interface to be interconnected with the peripheral circuit 201, where a connection structure of the gate layer 112 is blocked and is not shown due to the cross-sectional orientation.

For example, there may be interconnection layers between the first bonding contact 171 and the third connection structure 143, such as the interconnection layers Array M1 to Array M3 as shown in FIG. 3.

In some implementations, referring to FIG. 4, the second semiconductor structure 21 is bonded to the first semiconductor structure 11 on a side of the bit line 121 away from the transistor 110. The structure of the peripheral circuit 201 in the second semiconductor structure 21 may not be limited, and may include, but is not limited to, various CMOS circuits composed of a plurality of transistors.

The structure of the transistor is not limited, and may include, but is not limited to, a planar transistor, a vertical transistor, a fin transistor, an all-around gate transistor, or the like.

The second semiconductor structure 21 may include a connection structure extending along the z-direction, such as the fifth connection structure 211, and the peripheral circuit 201 may be coupled to the bonding contact 172 (or the second bonding contact 221) through the fifth connection structure 211 to lead the electrical signal to the bonding interface to be interconnected with the first semiconductor structure 11.

In some implementations, an interconnection layer 212 may be disposed between the fifth connection structure 211 and the second bonding contact 221, a side of the interconnection layer 212 close to the first semiconductor structure 11 is coupled to the bonding contact, and a side of the interconnection layer 212 away from the first semiconductor structure 11 is coupled to each device of parts of the peripheral circuit 201.

The interconnection layer 212 may include wiring layers stacked in the z-direction, where adjacent wiring layers are coupled through a conductive plug, such as CMOS M1 to CMOS TM as shown in FIG. 3.

In some implementations, the capacitor structure 130 coupled to the transistor 110 shown in FIG. 4 is configured as a storage capacitor. The first semiconductor structure 11 further includes some capacitor structures 130′ not shown which are not coupled to the transistors 110, and the capacitor structures 130′ are configured as a decoupling capacitor or a de-noising capacitor for reducing a noise interference with a signal, and increasing the stability of power supplying and signal interconnection, and the capacitor structures 130′ are coupled to the peripheral circuit 201 through a connection structure, an interconnection layer, and a bonding contact 172. The plurality of storage capacitors form a storage capacitor array, and the plurality of decoupling capacitors or the decoupling capacitor array are located in an edge region of the storage capacitor array.

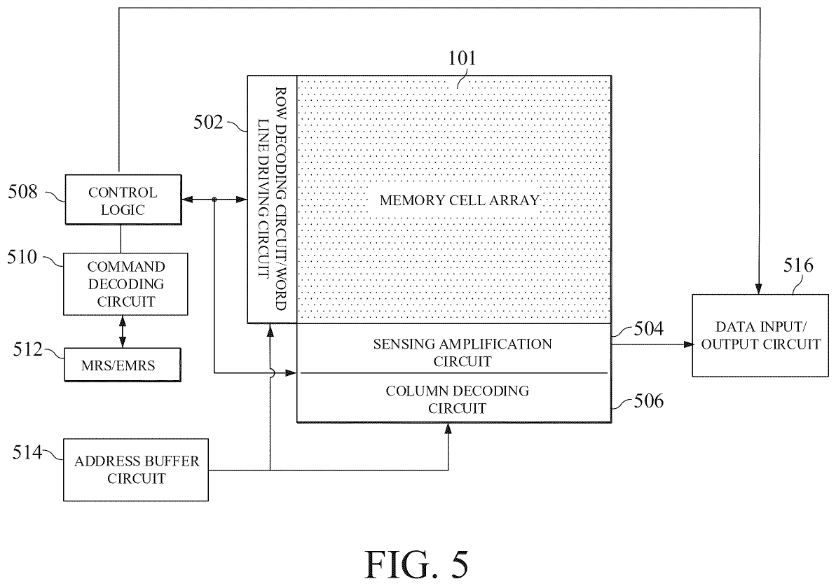

In some implementations, FIG. 5 illustrates an example of a peripheral circuit 201 for a memory apparatus 10. Peripheral circuit 201 may be coupled to memory cell array 101 at least through bit lines 121 and word lines. The example peripheral circuit 201 may include a row decoding circuit/word line driving circuit 502, a sensing amplification circuit 504, a column decoding circuit 506, a control logic 508, a command decoding circuit 510, a mode register setting circuit (MRS/EMRS) 512, an address buffer circuit 514, and a data input/output circuit 516. In some examples, additional peripheral circuits not shown in FIG. 5 may also be included, and FIG. 5 is merely an example to facilitate explanation of implementations of the present disclosure.

The sensing amplification circuit 504 may sense and amplify the data of the memory cell and may store the data in a memory cell. The sensing amplification circuit 504 may be implemented by a cross-coupled amplifier connected between a bit line 121 and a complementary bit line 121 included in the memory cell array 101.

The data input/output circuit 516 may write the input data to the memory cell array 101 based on the address signal (ADD), and may read the output data from the memory cell array 101 based on the address information (ADD) and output the data to the outside of the memory apparatus. To specify a memory cell for writing or reading data, an address signal (ADD) may be input to the address buffer circuit 514, which may temporarily store address signal (ADD).

The row decoding circuit/word line driving circuit 502 may decode the row address in the address signal (ADD) output from the address buffer circuit 514 to specify the word line connected to the memory cell for writing or reading data.

For example, when performing a write or read operation, the row decoding circuit/word line driving circuit 502 may decode the row address output from the address buffer circuit 514 to enable the word line corresponding to the row address. As another example, when performing a refresh operation, the row decoding circuit/word line driving circuit 502 may decode the row address generated by the address counter to enable the word line corresponding to the row address.

The column decoding circuit 506 may decode the column address in the address signal (ADD) output from the address buffer circuit 514 to specify the bit line 121 connected to the memory cell for writing or reading data. The memory cell array 101 may read data from or write data to memory cell specified by the row address and the column address.

The command decoding circuit 510 may receive command signals (CMD) from a host or a memory controller, and may internally generate decoded command signals by decoding these signals.

The MRS/EMRS circuit 512 may set the mode register in response to an MRS/EMSS command specifying the operating mode of the memory component or device.

The peripheral circuit 201 may also include a clock circuit for generating a clock signal, a power supply circuit for generating or distributing internal voltages by receiving a supply voltage applied externally thereto, or the like.

The control logic 508 may be coupled to various circuits of each of the peripheral circuits 201 described above and configured to control operation of each of the peripheral circuits 201.

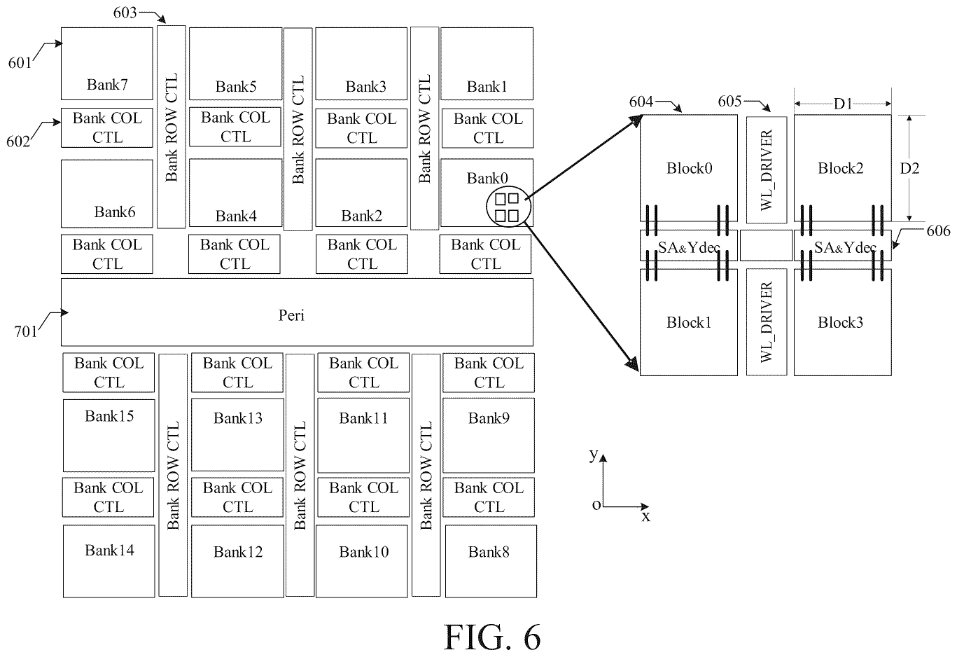

In some implementations, FIG. 6 provides a schematic diagram of a layout of a memory apparatus 10, and according to a layout design of the memory apparatus 10, a memory cell array 101 may be divided into a plurality of memory banks 601 and the memory bank 601 may be divided into a plurality of memory blocks 604, where the memory block 604 includes a plurality of memory cells arranged along the x-direction and y-direction as illustrated in FIG. 1 and FIG. 4, and further includes some of the bit lines 121 and word lines (or gate layers 112), and the memory bank 601 includes an array of memory blocks 604 arranged along the x-direction and y-direction; and one memory apparatus 10 may include a plurality of memory banks 601, and one memory device may include at least one memory apparatus 10.

In some implementations, to adapt the division of the memory bank 601 and the memory block 604, the peripheral circuit 201 may include a control circuit corresponding to a memory cell array having multiple levels, which is beneficial for reducing the control pressure of the peripheral circuit 201 and improving the access rate. The peripheral circuit 201 may include a control circuit corresponding to a level of the memory bank 601, and a control circuit corresponding to a level of the memory bank 604.

The control circuits for the levels of individual memory blocks 604 are altogether connected to the control circuit for the level of the memory bank 601 by interconnection lines (local interconnection lines), and the control circuits for the levels of the individual memory bank 601 are altogether connected to other common regions of the peripheral circuit 201, such as control logic 508, by the interconnection lines (primary bus). The control logic 508 is configured to receive an instruction from a host or a memory controller, and perform a read, write, or refresh operation on the memory cell array 101.

In some implementations, referring to FIG. 6, the peripheral circuit 201 may include a memory bank control circuit including a memory bank row control circuit 603 (Bank ROW CTL) between two adjacent memory banks 601 in the x-direction (row direction), and may include a memory bank row decoder, which may be configured to address a row where the memory bank 601 is located and apply an operating voltage to the word line.

The control circuit for the memory bank 601 further includes a memory bank column control circuit (Bank COL CTL) between two adjacent memory banks 601 in the y-direction (column direction), such as a memory bank column decoder, which may be configured to address a column where the memory bank 601 is located, and may be configured to be coupled to a bit line, apply a bit line voltage, or receive a bit line voltage.

In some other implementations, as shown in FIG. 6, the peripheral circuit 201 is located in a gap region (Peri) between the memory banks 601, which is configured to provide an interaction circuit with a host or a memory controller or a common circuit that controls interaction between individual levels of the memory banks 601, including but not limited to: a control logic 508, various levels of data paths, a data path control circuit, a voltage generation circuit, a command decoding circuit 510, a data input/output circuit 516, and the like, for data interaction between the memory banks 601, for data interaction with the host, and for generating different voltages to supply power.

In some implementations, referring to FIG. 6, a word line driving circuit 605 (or a word line driver) is disposed between two adjacent memory blocks 604 in the x-direction (row direction) to apply a voltage to a selected word line; and a sensing amplification circuit (SA) 606 and a column decoding circuit (Ydec) are disposed between two adjacent memory blocks 604 in the y-direction (column direction).

The peripheral circuit 201 includes a plurality of sensing amplification circuits 606, each of the sensing amplification circuits 606 is coupled to two adjacent bit lines in the y-direction, the sensing amplification circuits 606 may be coupled to each other through a connection circuit, and the plurality of sensing amplification circuits 606 may be interconnected by a connection circuit.

Sensing amplification circuit 606 is coupled to two bit lines, where the sensing amplification circuits 606 may operate by using a selected bit line and a complementary bit line as a reference line to detect and amplify a voltage difference across a pair of bit lines.

The column decoding circuit is coupled to a plurality of columns of bit lines in a corresponding memory block 604, and is configured to receive the column address signal, decode the column address signal, and output a column select signal indicating to activate the corresponding bit line in the memory block 604 in the enable state.

In some implementations, the peripheral circuit 201 and the memory cell array 101 of the memory apparatus 10 shown in FIG. 6 may be in the same wafer or in the same semiconductor structure, or be in different semiconductor structures shown in FIG. 2 to FIG. 4, where the two portions are bonded and interconnected by an electrical signal.

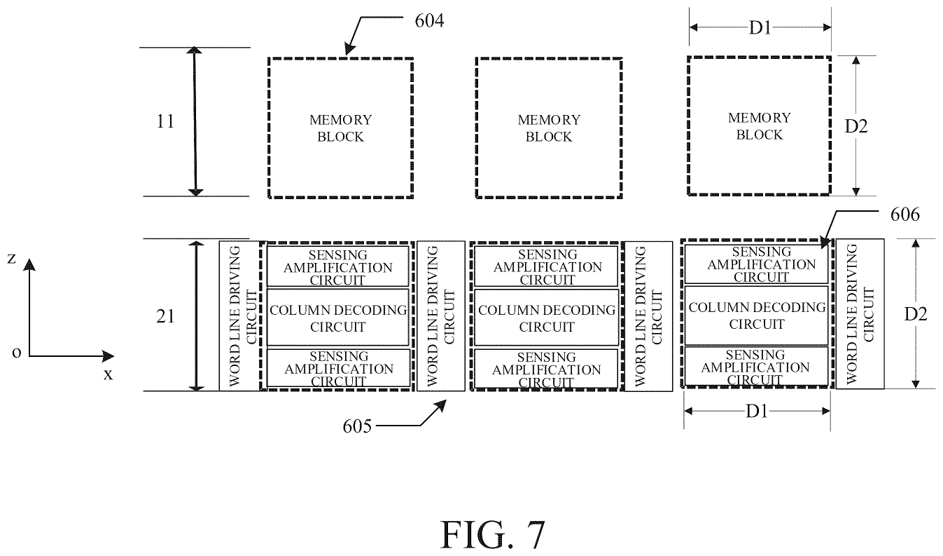

Referring to FIG. 7, a schematic diagram of a relative relationship between one memory bank 601 in the memory cell array 101 of the first semiconductor structure 11 and a portion of the peripheral circuit 201 in the second semiconductor structure 21 is shown. The word line driving circuit 605 shown in FIG. 7 may be located outside the memory block 604, and the sensing amplification circuit 606, the column decoding circuit or the like may be located within the orthographic projection of the memory block 604 along the z-direction, which is beneficial to improve the integration level of the peripheral circuit 201 and the memory cell array 101 while facilitating the wiring. The peripheral circuit of the second semiconductor structure 21 in FIG. 7 may further include an interconnection device or another circuit.

Alternatively, the widths of the memory block 604 in the x-direction and the y-direction are denoted as D1 and D2 respectively, the corresponding sensing amplification circuit 606 and the column decoding circuit are disposed within the width D1 and the width D2 of the memory block 604, and the word line driving circuit 605 is disposed outside the width D1 of the memory block 604.

Alternatively, the word line driving circuit 605 may be moved inward to be disposed within the width D1 of the memory block 604 and located within the orthographic projection of the memory block 604 along the z-direction.

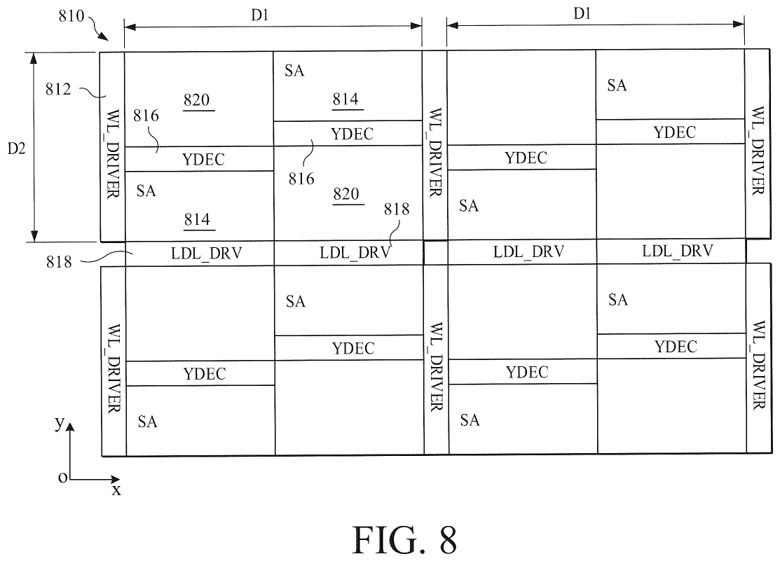

In some implementations, FIG. 8 shows an example of a portion of peripheral circuit 201 corresponding to or overlapping the memory block 604 in the z-direction, and since the word line driving circuit corresponds to a region between two adjacent memory blocks 604 in the x-direction, the area occupied by the portion of peripheral circuit 201 is larger than that of the memory block 604.

As shown in FIG. 8, the second semiconductor structure 21 may include four groups of control circuits (e.g., including some peripheral circuits 201 as shown in FIG. 5) stacked with four adjacent memory blocks 604. The second semiconductor structure 21 may include other numbers of groups of control circuits. For ease of explanation, the first group of control circuits 810 are described in detail, and the remaining groups of control circuits may be the same as or substantially similar to the first group of control circuits 810.

As shown in FIG. 8, the first group of control circuits may include a driver circuit including the word line driving circuit 812, a sensing circuit including the sense amplification circuit 814, the column decoding circuit 816, and remaining circuits 820.

Each word line driving circuit 812 is coupled to a word line in the first semiconductor structure 11, where the word line is coupled to a row of memory cells in a memory block 604 stacked with the first group of control circuits 810.

Each sensing amplification circuit 814 is coupled to a bit line in the first semiconductor structure 11, where the bit line is coupled to a column of memory cells in a memory block 604 stacked with the first group of control circuits 810.

The sense amplification circuit 814 is coupled to the column decoding circuit 816 to decode the column address, and is coupled to the data line driving circuit 818 to receive a signal to select/deselect the bit line.

The remaining circuits 820 may include other portions of peripheral circuit 201, such as command decoding circuit, address buffer circuit, or the like.

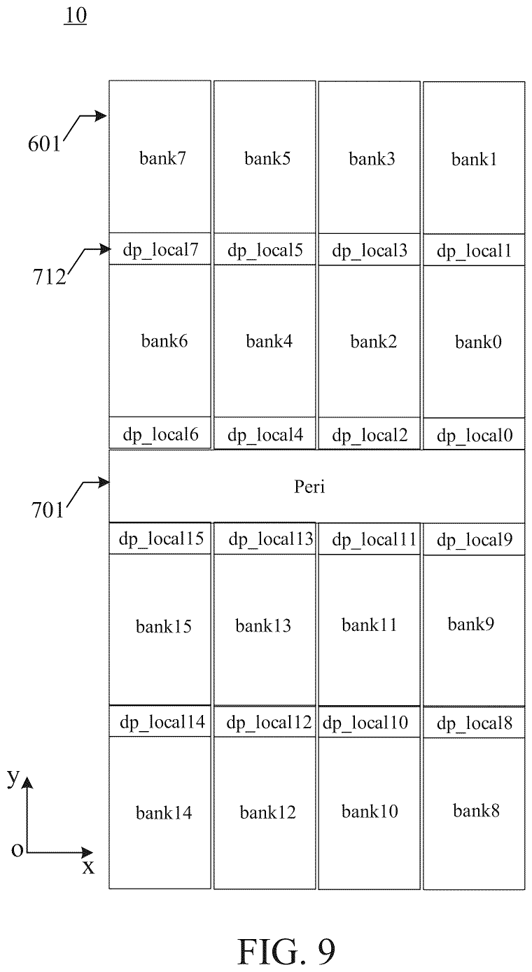

In some implementations, referring to FIG. 9 showing the layout of the memory apparatus 10, a portion of regions of the peripheral circuit 201 is located in a gap region Peri between two memory banks 601 in the y-direction, which may be denoted as a first peripheral region 701 or an middle peripheral region (MID_Peri), where a plurality of rows of memory banks are respectively disposed on two sides of the first peripheral region 701 in the y-direction.

For example, two rows of memory banks are respectively disposed on two sides of the first peripheral region 701 in the y-direction, with a total of 4 rows of memory banks. The first peripheral region 701 may include at least a first data path circuit, which is configured to transmit data and a control signal to each memory bank 601.

The first data path circuit may include a multi-level data path and a first data path control circuit; for example, the first data path circuit may include a global transmission line, which may include a control line for transmitting control signals and a data transmission line for transmitting written or reading data. For example, the global transmission line may include a global control line and a global data transmission line.

A gap region between the individual memory banks in FIG. 9 and a gap region between the memory banks and the first peripheral region 701 in FIG. 9 are omitted, where the memory bank column control circuit 602 and the memory bank row control circuit 603 may disposed in these gap regions, as shown in FIG. 6.

In some implementations, a second data path circuit 712 (dp_local) is disposed between the adjacent memory banks 601 and between the memory banks 601 and the first peripheral region 701, and one second data path circuit 712 is connected to one corresponding memory bank 601. For example, the second data path circuit 712 may be interconnected with the memory cells at least through the control circuit of the memory bank 601 and the word line driving circuit and the column select circuit at a level of the memory block 604 to control operations of the memory cells, such as read, write, refresh, and the like.

The second data path may further include a second data path control circuit to control transmission of an electrical signal. Each dp_local is coupled to the first data path circuit; for example, each dp_local is coupled to the global transmission line through a local transmission line, and the global transmission line may be coupled to a control logic, an input or output circuit, or another circuit to complete an electrical signal interaction path of the memory controller or the host.

The local transmission line may include a local control line and a local data transmission line, and the local transmission line may be or may not be part of the first data path circuit, where each memory bank has a group of local transmission lines corresponding to the memory bank or belonging to the memory bank, and the communication and interconnection between individual memory banks may be achieved by a global transmission line and a local transmission line belonging to the memory bank.

In some implementations, memory banks in FIG. 9 may be located in the first semiconductor structure 11, a portion of the peripheral circuit 201 including the first peripheral region 701 and the dp_local is located in the second semiconductor structure 21, where the memory banks 601 and the peripheral circuit 201 are in electrical signal interconnection by a hybrid bonding, and the memory banks 601 and the peripheral circuit 201 are at different layer heights or at different levels in the z-direction.

A capacitor structure 130′ may be disposed in a region of the first semiconductor structure 11 corresponding to the first peripheral region 701, and the capacitor structure 130′ is not configured as a storage capacitor, may be connected to the peripheral circuit 201 through a bonding contact, and is configured as a decoupling capacitor or a de-noising capacitor for reducing a noise interference with a signal.

It can be understood that, when the memory banks 601 and the peripheral circuit 201 at the same wafer or different wafers are bonded, and dp_local corresponding to the memory bank 601 at the outer side such as bank1, bank7, bank8, or bank14 is coupled to the global transmission line through the local transmission line, it needs to pass through the region of the memory bank 601 at the inner side along the y-direction, which will occupy the circuit region of the memory bank 601 at the inner side, causing signal interference between different lines and being harmful to the improvement of the integration level of the memory apparatus.

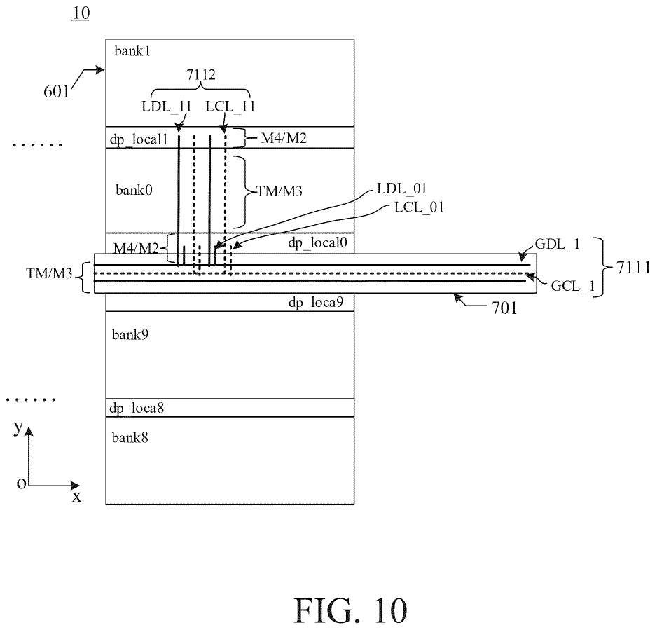

In an example, referring to FIG. 10, taking bank1 and bank0 as an example, a line for transmitting a control signal such as a control instruction and an address signal is illustrated by a dashed line in the figure, and a line for transmitting read and written data is illustrated by a solid line in the figure.

The number of bits in a transmission line for each level and the number of transmission lines for each level are not limited, the serial and parallel transmission of transmission lines for each level are not limited, and the clock timing for transmission lines for each level is not limited.

The global transmission line 7111 is located in the first peripheral region 701, and may include at least a global control line GCL_1 and a global data transmission line GDL_1; and the local transmission line 7112 corresponding to the memory bank 601 may include a local control line and a local data transmission line. dp_local1 corresponding to bank1 is coupled to global control line GCL_1 through local control line LCL_11, and is further coupled to global data transmission line GDL_1 through local data transmission line LDL_11; and dp_local0 corresponding to bank0 is coupled to global control line GCL_1 through local control line LCL_01, and is further coupled to global data transmission line GDL_1 through local data transmission line LDL_01.

The number of local transmission lines LCL and LDL belonging to each memory bank is not limited. In order to accommodate a line transmission bandwidth and a capacity of the memory bank, a plurality of GCLs and GDLs may be disposed.

For example, a part of dp_locals is coupled to GCL_1 and GDL_1 through the local transmission lines 7112 belonging thereto, while other dp_locals are coupled to GCL_2 and GDL_2 through the local transmission line 7112 belonging thereto.

In some example implementations, referring to FIG. 10, the local transmission line 7112 (such as LDL_11 and LCL_11) belonging to bank1 (or dp_local1) at the outer side may pass through bank0 to be coupled to the global transmission line 7111, which may occupy a circuit area of bank0 to a certain extent and increase signal interference.

In order to reduce area occupation and reduce signal interference between transmission lines, different transmission lines may be in different interconnection layers, and different interconnection layers are in layers of the semiconductor structure at different levels, which facilitates reducing occupation of the device area on the same horizontal plane by the transmission lines, and also facilitates reducing signal interference.

For example, portions of the local transmission lines LDL_11 and LCL_11 passing through bank0 in FIG. 10 are respectively located in the interconnection layer TM and the interconnection layer M3, or are respectively located in the interconnection layer M3 and the interconnection layer TM; portions of the LDL_11 and the LCL_11 not passing through bank0 are respectively located in the interconnection layers M4 and M2, or are respectively located in the interconnection layers M2 and M4; and the global transmission lines GDL_1 and GCL_1 are respectively located in the interconnection layers TM and M3, or are respectively located in the interconnection layers M3 and TM.

In some implementations, with the layout of the memory banks and the peripheral circuit 201 shown in FIG. 10, the word lines and the bit lines in the memory banks can be coupled to the peripheral circuit 201 at least through the bonding contacts 172 in FIG. 4.

As compared with the solution in which the memory banks and the peripheral circuit 201 are placed on the same wafer, the bonding solution according to the implementation of the present disclosure can reduce the wiring paths of the peripheral circuit 201 by one third.

However, due to the arrangement of multiple rows of memory banks on both sides of the first peripheral region 701, the wiring for the dp_local belonging to memory banks at the outer side needs to pass through the region of the memory bank at the inner side.

For example, the wirings (e.g., LDL_11 and LCL_11) of dp_local1 need to pass through the region of bank0, thereby occupying the wiring region of bank0, resulting in insufficient wiring of bank0.

In some implementations, a row of memory banks may be disposed on both sides of the first peripheral region 701 of the peripheral circuit 201 shown in FIG. 10, so that the local transmission line 7112 belonging to the memory bank at the outer side passing through the region of the memory bank at the inner side is reduced, the occupation of a circuit region of the memory bank at the inner side by the local transmission line 7112 belonging to the memory bank at the outer side is reduced, the layout design of the wiring layer is optimized, and signal interference between the transmission lines is reduced.

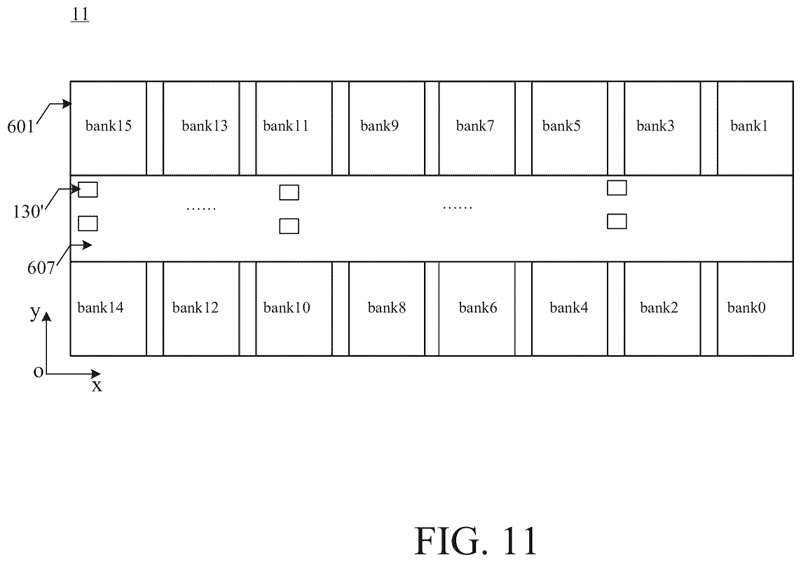

According to some aspects of the implementations of the present disclosure, a memory apparatus 10 is provided, including the first semiconductor structure 11 illustrated in FIG. 4 and FIG. 11; and the second semiconductor structure 21 illustrated in FIG. 4 and FIG. 11. The first semiconductor structure 11 includes a memory cell array 101, and a first bonding layer 170 including a plurality of first bonding contacts 171, where the memory cell array 101 includes a plurality of memory banks 601 as shown in FIG. 11, and the plurality of memory banks 601 are arranged in two rows along the first direction (x-direction); and there is a first region 607 between the two rows of memory banks 601 in the second direction (y-direction) intersecting with the x-direction.

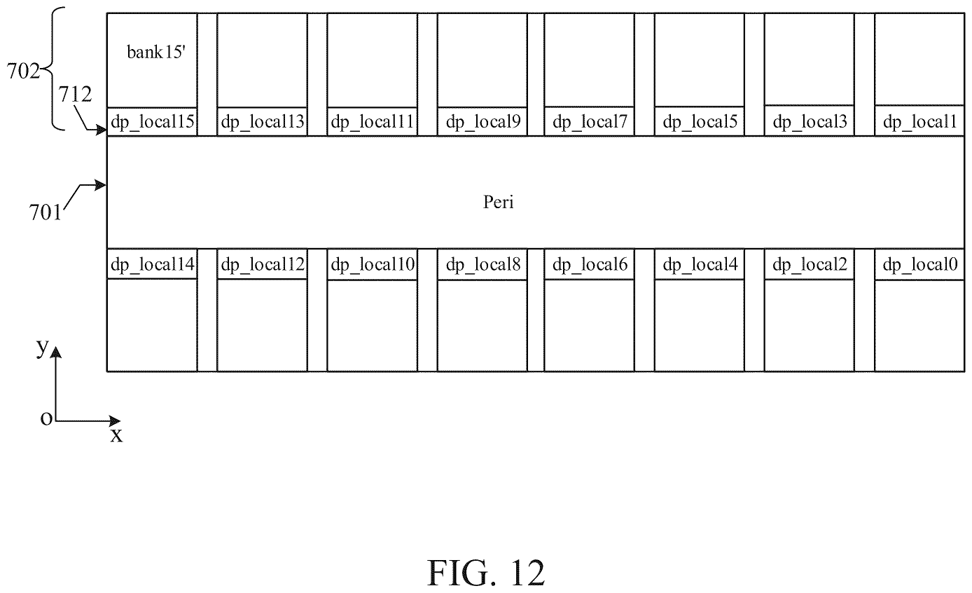

The second semiconductor structure 21 includes the peripheral circuit 201 shown in FIG. 4 and a second bonding layer 220 having a plurality of second bonding contacts 221, where the peripheral circuit 201 includes a first peripheral region 701 and a plurality of second peripheral regions 702; a circuit of the first peripheral region 701 is at least partially different from that of the second peripheral region 702; the first bonding layer 170 and the second bonding layer 220 are bonded in the z-direction; and the first bonding contact 171 and the second bonding contact 221 are coupled, where the first peripheral region 701 in FIG. 12 corresponds to at least a part of the first region 607 in FIG. 11 in the z-direction, and one of the second peripheral regions 702 corresponds to at least a part of one of the memory banks 601 in the z-direction, where the plane formed by the x-direction and the y-direction intersects with the z-direction.

In some implementations, as illustrated in FIG. 11, the memory apparatus 10 has two rows of memory banks 601, where one row of memory banks 601 includes a plurality of memory banks 601 arranged along the x-direction.

In some implementations, the first peripheral region 701 overlaps at least a part of the first region 607 in the z-direction, and one of the second peripheral regions 702 overlaps with at least a part of one of the memory banks 601 in the z-direction.

In an example, a schematic diagram of the device layout of the first semiconductor structure 11 and the second semiconductor structure 21 in the xoy plane may be illustrated in FIG. 11 and FIG. 12 respectively. The example structure of the apparatus formed by bonding the first semiconductor structure 11 and the second semiconductor structure 21 in the z-direction may be shown in FIG. 4.

In FIG. 11, the number of the memory banks 601 arranged in the x-direction is not limited, the first region 607 between the two rows of memory banks 601 in the y-direction may or may not belong to a portion of the memory cell array 101, and the first region 607 corresponds to the first peripheral region 701 (or the middle peripheral region Mid Peri) in FIG. 12 in the z-direction, where a corresponding electrical coupling between the first region 607 and the first peripheral region 701 may be included, and the first region 607 and the first peripheral region 701 may be aligned and bonded in the z-direction. When bonding, the first region 607 and the first peripheral region 701 may at least partially overlap.

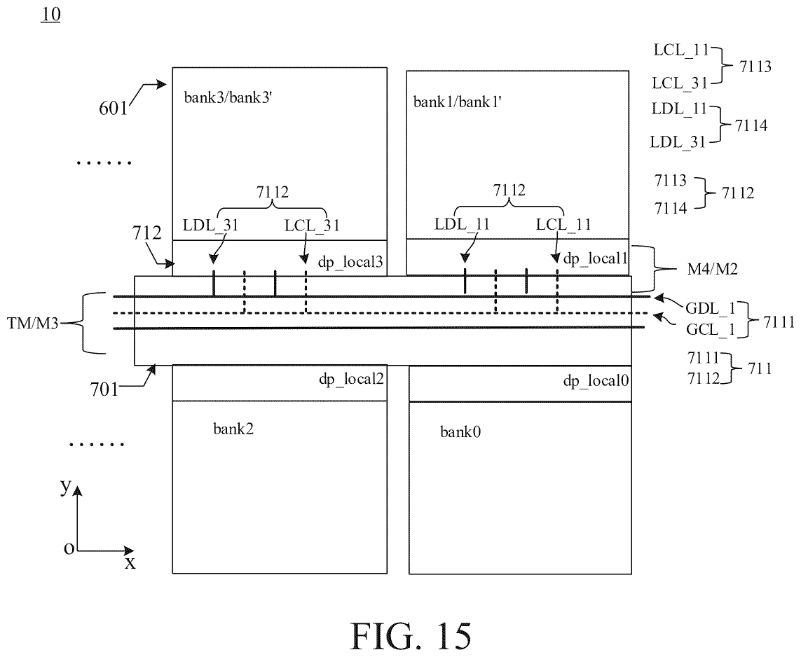

The first data path circuit 711 illustrated in FIG. 15 may be disposed in the first peripheral region 701 of FIG. 12, where the second data path circuit 712 (dp_local) corresponding to the memory bank is disposed on two sides of the first data path circuit 711 in the y-direction, and the second data path circuit 712 may be located outside the first peripheral region 701 and located in the second peripheral region 702.

Alternatively, in other examples, dp_local may be located outside the second peripheral region 702, or may be located in the first peripheral region 701, or may be located between the first peripheral region 701 and the second peripheral region 702.

A second peripheral region 702 in FIG. 12 corresponds to a memory bank, and at least partially overlaps with the memory bank in the z-direction, where the second peripheral region 702 includes at least dp_local and a region corresponding to a memory bank, such as dp_local15 and a region of bank15′ corresponding to bank15, and a portion of the peripheral circuit 201 (shown in FIG. 8) corresponding to the memory block 604 may be disposed in the region of bank15', and therefore, the circuit area of the second peripheral region 702 may be greater than the circuit area of the memory bank 601.

An example of the first data path circuit 711 and the second data path circuit 712 is illustrated in FIG. 15 below. After the memory cell array 101 is bonded to the peripheral circuit 201, the bank15′ is aligned or substantially aligned with bank15, and the circuit area of bank15′ may be greater than or equal to that of bank15. In other examples, the second peripheral region 702 may include only the region of bank15', but not include dp_local15.

In some implementations, the interconnection layer or the first bonding contact 171 may be disposed in the first region 607 to facilitate the lead-out of lines.

Alternatively, the capacitor structure 130′ may be disposed in the first region 607 as illustrated in FIG. 11, where the capacitor structure 130′ in the first region 607 may not be coupled to the transistor 110, and is coupled to the peripheral circuit 201 through the connection structure, the interconnection layer, and the bonding contact, and the capacitor structure 130′ in the first region 607 is configured as a decoupling capacitor or a de-noising capacitor for reducing a noise interference with a signal and increasing a stability of power supplying and signal interconnection.

Alternatively, the first bonding contact 171 disposed in the first region 607 serves as a dummy contact, which is not configured to perform electrical signal interconnection but to increase the bonding strength. In other implementations, other devices may also be disposed in the first region 607, which may include, but are not limited to, an interconnection line, a conductive plug, a transistor, a capacitor, or the like.

Alternatively, a supporting structure may be disposed in the first region 607 to reduce deformation and collapse of the memory apparatus.

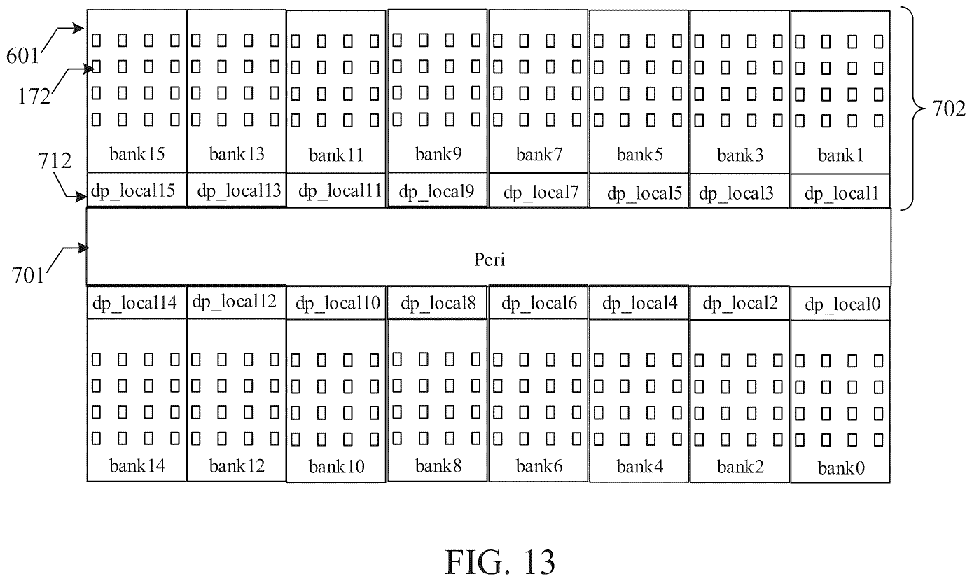

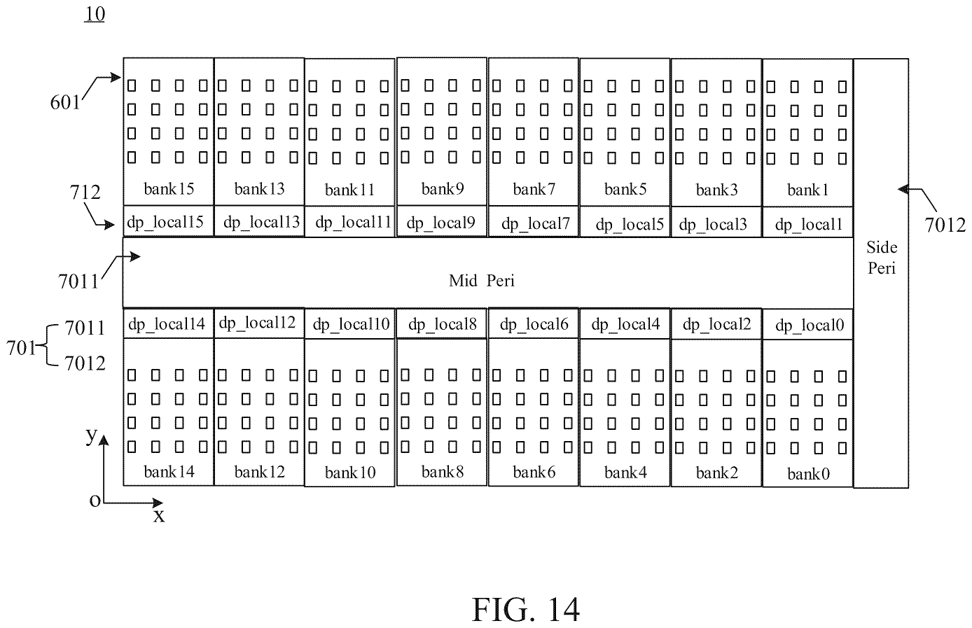

In some implementations, FIGS. 13 and 14 illustrate a schematic diagram of a layout of the memory apparatus 10 after the memory cell array 101 is bonded to the peripheral circuit 201, and illustrate the bonding contact 172 located in the region of each memory bank 601. In some other implementations, a bonding contact may be disposed in the first peripheral region 701 to couple to the decoupling capacitor in the first region 607 in FIG. 11.

In some implementations, referring to FIG. 13, the first peripheral region 701 may be disposed only in a gap region between two rows of second peripheral regions 702. That is, a strip-shaped first peripheral region 701 extending along the x-direction is disposed. An interaction circuit with a host or a memory controller or a common circuit for controlling interaction between memory banks 601 at each level may be disposed or included in the first peripheral region 701, including but not limited to: a control logic, various levels of data paths, a data path control circuit, a voltage generation circuit, a command decoding circuit, and a data output/input circuits, etc., for data interaction between the memory banks 601, also for data interaction with the host, and also for generating different voltages for supplying power. In some other implementations, the first peripheral region 701 may include a sub-region. For example, a peripheral region may be disposed at an edge of the memory bank 601 at the outermost side in the x-direction.

In some implementations, referring to FIG. 14, the first peripheral region 701 includes: a first sub-peripheral region 7011 located between adjacent second peripheral regions 702 in the y-direction; and a second sub-peripheral region 7012 located on a side of the first sub-peripheral region 7011 in the x-direction and also on a side of the two rows of second peripheral regions 702 in the x-direction.

Referring to FIG. 14, the first peripheral region 701 is a T-shaped region, the first sub-peripheral region 7011 is illustrated by Mid Peri, and the second sub-peripheral region 7012 is located at an outermost side of the array of the memory banks 601 in the x-direction, such as at the outermost sides of bank1 and bank0, as illustrated by Side Peri. The first sub-peripheral region 7011 may be provided with or include, but is not limited to, a first data path circuit 711 or a control logic, and the second sub-peripheral region 7012 may be provided with or include, but is not limited to, an output/input circuit, or a power supply circuit such as a voltage generation circuit.

In some implementations, at least one of the first peripheral region 701 in FIG. 12 and FIG. 13 or the first sub-peripheral region 7011 in FIG. 14 may at least include the first data path circuit 711 illustrated in FIG. 15 configured to transmit at least one of a control instruction, an address signal, or data.

The first data path circuit 711 may include a multi-level data path and a first data path control circuit. For example, the first data path circuit 711 may include a global transmission line 7111, which may include a control line for transmitting control signals and a data transmission line for transmitting the written or read data. For example, the global transmission line 7111 may include a global control line GCL_1 and a global data transmission line GDL_1.

A gap region between individual memory banks, and a gap region between the memory banks and the first peripheral region 701 are omitted, where the memory bank column control circuit 602 and the memory bank row control circuit 603 may disposed in these gap regions, as shown in FIG. 6.

In some implementations, the plurality of second peripheral regions 702 are arranged at an interval in two rows along the x-direction, and the two rows of second peripheral regions 702 are respectively located on two sides of the first peripheral region 701 in the y-direction.

A first memory bank of the plurality of memory banks 601 includes a plurality of memory blocks 604, where the second peripheral region 702 corresponding to the first memory bank includes at least: the word line driving circuit 812 (WL_DRIVER), the column decoding circuit 816 (YDEC), and the sensing amplification circuit 814 (SA) corresponding to the memory blocks 604 in the first memory bank, as shown in FIG. 8.

A portion of the peripheral circuit 201 (shown in FIG. 8) corresponding to individual memory blocks 604 may be located at least in the region of bank15′ in FIG. 12, and FIG. 8 shows four groups of control circuits which may correspond to 4 memory blocks 604 in the first memory bank (for example, bank15), where any one of the memory blocks 604 in bank15, for example, the first memory block, may correspond to a group of control circuits, for example, the first group of control circuits 810, and the remaining groups of control circuits may be the same as or substantially similar to the first group of control circuits 810. For example, the first group of control circuits 810 may include a driver circuit including the word line driving circuit 812, a sensing circuit including the sensing amplification circuit 814, the column decoding circuit 816, and the remaining circuits 820, or the like.

In some implementations, the control circuit groups of all memory blocks 604 belonging to the first memory bank bank15 in FIG. 11 may be located in bank15′ in FIG. 12, and may be bonded to bank15 in the z-direction, and the control circuit group corresponding thereto may be for example the first group of control circuits 810 in FIG. 8. In some implementations, each memory block 604 or the data line driving circuit 818 shown in FIG. 8 corresponding to each memory block 604 may be coupled to the second data path circuit 712, and further may be coupled to the first data path circuit 711, but the present disclosure is not limited thereto.

In some implementations, the peripheral circuit 201 illustrated in FIG. 12 further includes the memory bank column control circuit 602 between the second peripheral region 702 and the first peripheral region 701; and the memory bank row control circuit 603 located in the gap region between two adjacent second peripheral regions 702 in the x-direction, as illustrated in FIG. 6.

In FIG. 12, taking the first memory bank bank15 as an example, the corresponding memory bank column control circuit 602 may be located between bank15′ and the first peripheral region 701, and the memory bank column control circuit 602 may also be located within or outside the second peripheral region 702.

In some implementations, referring to FIG. 12 and FIG. 13, the peripheral circuit 201 further includes: a plurality of second data path circuits 712 (dp_local) located on two sides of the first data path circuit 711 in the y-direction, where the second data path circuit 712 corresponds to the memory bank 601, and the second data path circuit 712 is coupled to the first data path circuit 711.

In some implementations, referring to FIG. 15, the first data path circuit 711 may include a global transmission line 7111 and a local transmission line 7112, and the second data path circuit 712 is coupled to the global transmission line 7111 through the local transmission line 7112.

In some implementations, referring to FIG. 15, the local transmission line 7112 includes a control line (local control line 7113) and a data transmission line (local data transmission line 7114), and the local control line 7113 and the local data transmission line 7114 are in different interconnection layers in the z-direction. An enable signal and address information are sent to a target memory bank 601 through the selected local control line 7113 to access the memory cell having the corresponding address; and the to-be-written data is sent to the target memory cell or the read data is output through the local data transmission line 7114.

Referring to FIG. 15, a second data path circuit 712 is correspondingly connected to a memory bank 601.

For example, the second data path circuit 712 may be interconnected with the memory cell at least through the control circuit for the memory bank 601, the word line driving circuit at the level of the memory block 604, the column selecting circuit or the like to control operations of the memory cell, such as read, write, refresh or the like.

The second data path circuit 712 may further include a second data path control circuit, which may generate an enable signal to control the selection and non-selection of the second data path circuit 712, thereby controlling whether the electrical signal may be transmitted. Each second data path circuit 712 is coupled to a first data path circuit 711.

For example, each second data path circuit 712 is coupled to a global transmission line 7111 through a local transmission line 7112, and the global transmission line 7111 may be coupled to a control logic, an input or output circuit, or another circuit to complete an electrical signal interaction path of the memory controller or the host.

The local transmission line 7112 may include a local control line 7113 and a local data transmission line 7114, each memory bank has a group of local transmission lines 7112 corresponding/belonging to this memory bank, and individual memory banks may be in communication and interconnection with each other by the global transmission line 7111 and the local transmission line 7112 belonging to the memory banks.

FIG. 15 shows memory bank bank3 or bank3′ in the second peripheral region corresponding to bank3, and the second data path circuit dp_local3 belonging thereto, and further shows memory bank bank1 or bank1′ corresponding to bank1, and the second data path circuit dp_local1 belonging thereto. A line for transmitting a control signal, such as a control instruction and an address signal, is illustrated by a dashed line in FIG. 15, and a line for transmitting read and written data is illustrated by a solid line in FIG. 15.

The number of bits in a transmission line for each level and the number of transmission lines for each level are not limited, the serial and parallel transmission of transmission lines for each level are not limited, and the clock timing for transmission lines for each level is not limited.

The local transmission line 7112 belonging to dp_local 1 includes a local control line LCL_11 and a local data transmission line LDL_11, and dp_local1 is coupled to the global control line GCL_1 and the global data transmission line GDL_1 through the LCL_11 and LDL_11 respectively.

The local transmission line 7112 belonging to dp_local 3 includes local control line LCL_31 and local data transmission line LDL_31, and dp_local3 is coupled to global control line GCL_1 and global data transmission line GDL_1 through LCL_31 and LDL_31 respectively.

The number of local transmission lines 7112 (LCL and LDL) belonging to each second data path circuit 712 is not limited. In order to accommodate a line transmission bandwidth and a capacity of the memory bank, a plurality of GCLs and GDLs may be disposed.

For example, a part of dp_locals is coupled to GCL_1 and GDL_1 through the local transmission line 7112 belonging thereto, while other dp_locals are coupled to GCL_2 and GDL_2 through the local transmission line 7112 belonging thereto.

In some implementations, as illustrated in FIG. 15, a portion of the local transmission line 7112 may be located in the first peripheral region 701, and thus may belong to a portion of the first data path circuit 711; and a portion of the local transmission line 7112 may extend into the second data path circuit 712, and may not be located in the first peripheral region 701.

The global transmission line 7111 may be located in the interconnection layer TM and the interconnection layer M3, where the global control line GCL and the global data transmission line GDL may be located in the interconnection layer TM and M3 respectively, or may be located in the interconnection layer M3 and TM respectively.

The local transmission line 7112 may be located in the interconnection layer M4 and the interconnection layer M2, where the local control line LCL and the local data transmission line LDL may be respectively located in different interconnection layers.

Therefore, a control line for each level and a data transmission line for each level are distributed in different interconnection layers to reduce signal transmission interference.

The CMOS M1 to CMOS TM in FIG. 3 may be referred for the relative positions of the interconnection layers in FIG. 15, where the CMOS TM is closest to the bonding contacts.

According to the implementation of the present disclosure, the two rows of memory banks are arranged on the two sides of the first region bonded with the first peripheral region, which can reduce a wiring distance of the local transmission line belonging to each memory bank, and facilitate reducing the number of wiring paths of the local transmission lines of a memory bank, reducing the occupation of a circuit area caused by the wiring from a region of the memory bank, and reducing the signal interference.

In some implementations, referring to FIG. 3, the second semiconductor structure 21 includes a plurality of interconnection layers (CMOS M1 to CMOS TM) stacked in the z-direction, where the plurality of interconnection layers are located between the peripheral circuit 201 and the second bonding contacts 221, the peripheral circuit 201 is coupled to the second bonding contacts 221 through the plurality of interconnection layers, and the adjacent interconnection layers may be coupled by a conductive plug. Similarly, the first semiconductor structure 11 may have a plurality of interconnection layers stacked in the z-direction.

In some implementations, referring to FIG. 16, the interconnection layers in the second semiconductor structure 21 may include stacked first and second interconnection layers, where the first interconnection layer includes a plurality of first interconnection lines 231 extending along a direction intersecting with the z-direction, the second interconnection layer includes a plurality of second interconnection lines 232 extending along a direction intersecting with the z-direction, and an extending direction of the first interconnection lines 231 intersects with an extending direction of the second interconnection lines 232; in a direction perpendicular to the z-direction, the first interconnection lines 231 are located between adjacent second bonding contacts 221; and in a direction perpendicular to the z-direction, the second interconnection lines 232 are located between adjacent second bonding contacts 221.

Referring to FIG. 16, the first interconnection layer may be the interconnection layer M2 or M4, which may be an example of the interconnection layer CMOS M2 or the CMOS M4 in FIG. 3; the second interconnection layer may be the interconnection layer M3 or TM, which may be an example of the interconnection layer CMOS M3 or the CMOS TM in FIG. 3; and the first interconnection layer and the second interconnection layer are not at the same layer height as the second bonding layer 220. A plurality of first interconnection lines 231 in the first interconnection layer M2 may extend along the x-direction, a plurality of second interconnection lines 232 in the second interconnection layer TM may extend along the y-direction, and the extending direction of the first interconnection lines 231 may intersect with the extending direction of the second interconnection lines 232 to reduce overlap area so as to reduce parasitic resistance and reduce signal interference. The first interconnect lines 231 are located between adjacent second bonding contacts 221, or between the first bonding contacts 171 bonded to the second bonding contacts 221, and the second interconnect lines 232 are located between adjacent second bonding contacts 221, or between the first bonding contacts 171 bonded to the second bonding contacts 221, thereby reducing signal interference between the interconnection lines and the bonding contacts.

For example, some of interconnection lines in the interconnection layer TM in FIG. 16 extending along the x-direction may serve as the global control lines GCL_1 to transmit the global control signals, and some of interconnection lines in the interconnection layer M4 extending along the y-direction may serve as the local control lines LCL_31 to transmit the local control signals, where the LCL_31 may be coupled to the GCL_1 through a conductive plug extending along the z-direction.

Some of interconnection lines in the interconnection layer M3 extending in the x-direction may serve as global data transmission lines GDL_1 to transmit global data, and some of interconnection lines in the interconnection layer M2 extend along the y-direction may serve as local data transmission lines LDL_31 to transmit local data, where LDL_31 may be coupled to GDL_1 through a conductive plug extending along the z-direction.

The interconnection layers Array M1 to Array TM in the first semiconductor structure 11 in FIG. 3 may also be arranged by referring to the layout setting of the interconnection layers in FIG. 16, and details thereof are not described herein again.

The first interconnection line 231 mentioned in the implementations of the present disclosure is only a collective term of a plurality of interconnection lines in the first interconnection layer, the second interconnection line 232 is only a collective term of a plurality of interconnection lines in the second interconnection layer, and the expressions “first” and “second” are only used to distinguish the different interconnection layers to which they belong, and do not limit the transmission signal and the configuration level thereof.

In the implementations of the present disclosure, there may be multiple interconnection lines in the same interconnection layer, interconnection lines in different regions or interconnection lines connecting different devices may receive different levels, voltages, or transmit different signals and data, different interconnection lines have different widths, and different interconnection lines may have different extending directions.

In some implementations, an extending direction of a portion of the first interconnection lines 231 corresponding to the first peripheral region 701 may intersect with an extending direction of a portion of the first interconnection lines 231 corresponding to the second peripheral region 702; and an extending direction of a portion of the second interconnection lines 232 corresponding to the first peripheral region 701 intersects with an extending direction of a portion of the second interconnection lines 232 corresponding to the second peripheral region 702.

Referring to FIG. 16, some of the first interconnection lines 231 in the first interconnection layer may be configured as a local transmission line 7112 at least partially located in the first peripheral region 701, such as the local control line LCL_31 or the local data transmission line LDL_31.

The local transmission line 7112 extends along the y-direction, and an extending direction of the local transmission line 7112 intersects with or is perpendicular to an extending direction of the first interconnection line 231 in the region of bank 3′ in the second peripheral region 702 and corresponding to the memory bank 601.

Second bonding contacts 221 may be disposed in the first peripheral region 701, and the local transmission line 7112 extends between the adjacent second bonding contacts 221 in the first peripheral region 701. Some of the second interconnection lines 232 in the second interconnection layer may be configured as a global transmission line 7111, such as a global control line GCL_1 or a global data transmission line GDL_1, located in the first peripheral region 701 and extending along the x-direction.

An extending direction of the global transmission line 7111 intersects with or is perpendicular to an extending direction of the second interconnection line 232 in the region of bank3′ in the second peripheral region 702 and corresponding to the memory bank 601.

In some implementations, referring to FIG. 4, the memory cell array 101 includes a transistor 110 including a first active region 114, a second active region 115, and a gate layer 112 extending along the y-direction; a bit line 121 extending along the x-direction and coupled to the first active region 114; and a capacitor structure 130 coupled to the second active region 115, where the peripheral circuit 201 is coupled to the bit line 121 through the first bonding contact 171 and the second bonding contact 221, and is coupled to the gate layer 112.

According to some aspects of the implementations of the present disclosure, a semiconductor structure is provided, such as the second semiconductor structure 21 illustrated in FIG. 4 and FIG. 12, and may include a peripheral circuit 201, where the peripheral circuit 201 includes a first peripheral region 701; and a plurality of second peripheral regions 702 arranged at an interval in two rows along the x-direction, the two rows of second peripheral regions 702 respectively located on two sides of the first peripheral region 701 in the y-direction intersecting with or being perpendicular to the x-direction; one first peripheral region 701 including at least the first data path circuit 711 illustrated in FIG. 15 configured to transmit at least one of a control instruction, an address signal, or data; and the second peripheral region 702 at least including the plurality of word line driving circuits 812, the plurality of column decoding circuits 816, and the plurality of sensing amplification circuits 814 illustrated in FIG. 8.

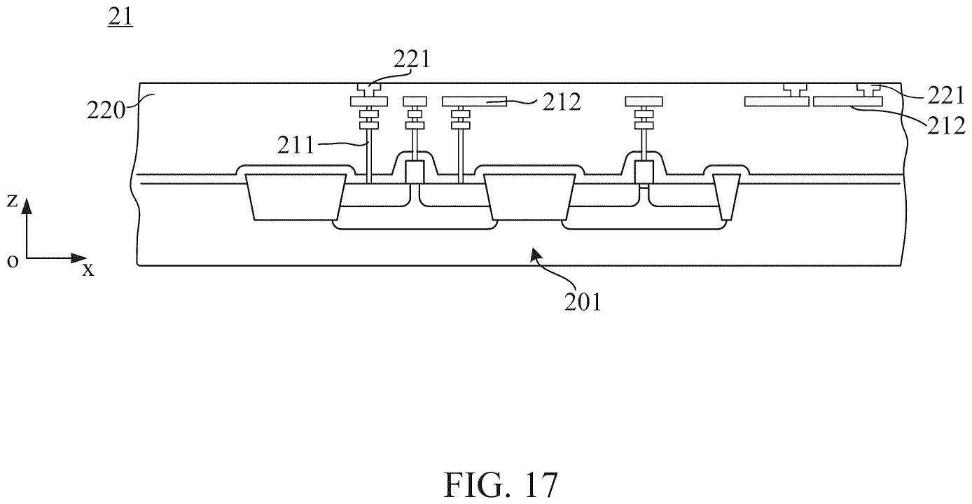

In some implementations, the second semiconductor structure 21 further includes a bonding layer having a plurality of bonding contacts, and the bonding contacts are coupled to at least a portion of a region of the peripheral circuit 201. The second bonding layer 220 as shown in FIG. 17 and FIG. 4 has a plurality of second bonding contacts 221.

The second semiconductor structure 21 may include a connection structure extending along the z-direction, such as a fifth connection structure 211, and the peripheral circuit 201 is coupled to the bonding contact 172 (or the second bonding contact 221) through the fifth connection structure 211 to lead the electrical signal to the bonding interface to be interconnected with the first semiconductor structure 11.

In some implementations, an interconnection layer 212 may be disposed between the fifth connection structure 211 and the second bonding contact 221, where a side of the interconnection layer 212 close to the first semiconductor structure 11 is coupled to the bonding contact, and a side of the interconnection layer 212 away from the first semiconductor structure 11 is coupled to a device of parts of the second semiconductor structure 21. The interconnection layer 212 may include wiring layers stacked in the z-direction, and adjacent wiring layers are coupled through a conductive plug.

In some implementations, referring to FIG. 12, the peripheral circuit 201 has two rows of second peripheral regions 702, where one row of second peripheral regions 702 includes a plurality of second peripheral regions 702 arranged along the x-direction.

In some implementations, the peripheral circuit 201 further includes a memory bank column control circuit 602 located between the second peripheral region 702 and the first peripheral region 701, and a memory bank row control circuit 603 located between two adjacent second peripheral regions 702 in the x-direction, as illustrated in FIG. 6.

In some implementations, referring to FIG. 14, the first peripheral region 701 includes a first sub-peripheral region 7011 located between adjacent second peripheral regions 702 in the y-direction, where at least a portion of the first data path circuit 711 is located in the first sub-peripheral region 7011; and a second sub-peripheral region 7012 located on a side of the first sub-peripheral region 7011 in the x-direction and located on a side of the two rows of second peripheral regions 702 in the x-direction.

In some implementations, referring to FIG. 15, the peripheral circuit 201 further includes a plurality of second data path circuits 712 located on two sides of the first data path circuit 711 in the y-direction, where one second data path circuit corresponds to one second peripheral region 702, and the second data path circuit 712 is coupled to the first data path circuit 711.

In some implementations, referring to FIG. 15, the first data path circuit 711 includes a global transmission line 7111 and a local transmission line 7112, and the second data path circuit 712 is coupled to the global transmission line 7111 through the local transmission line 7112.

In some implementations, referring to FIG. 15, the local transmission line 7112 includes a control line (local control line 7113) and a data transmission line (local data transmission line 7114), the local control line 7113 and the local data transmission line 7114 are in different interconnection layers in the z-direction, and a plane formed by the x-direction and the y-direction intersects with the z-direction.

In some implementations, the second semiconductor structure 21 further includes a plurality of interconnection layers (e.g., the CMOS M1 to CMOS TM shown in FIG. 3) stacked in the z-direction, the plurality of interconnection layers being located between the peripheral circuit 201 and the bonding contacts (the second bonding contacts 221), and the peripheral circuit 201 being coupled to the bonding contacts (the second bonding contacts 221) through the plurality of interconnection layers.

In some implementations, referring to FIG. 16, the interconnection layers in the second semiconductor structure 21 may include a first interconnection layer (interconnection layer M2 or M4) and a second interconnection layer (interconnection layer M3 or TM) that are stacked, where the first interconnection layer includes a plurality of first interconnection lines 231 extending along a direction intersecting with the z-direction, the second interconnection layer includes a plurality of second interconnection lines 232 extending along a direction intersecting with the z-direction, and an extending direction of the first interconnection lines 231 intersects with an extending direction of the second interconnection lines 232; in a direction perpendicular to the z-direction, the first interconnection lines 231 are located between adjacent bonding contacts; and in a direction perpendicular to the z-direction, the second interconnection lines 232 are located between adjacent bonding contacts.

In some implementations, referring to FIG. 16, an extending direction of a portion (e.g., the portion being the local transmission line 7112) of the first interconnection lines 231 corresponding to the first peripheral region 701 intersects with an extending direction of a portion of the first interconnection lines 231 corresponding to the second peripheral region 702, and an extending direction of a portion (e.g., the portion being the global transmission line 7111) of the second interconnection lines 232 corresponding to the first peripheral region 701 intersects with an extending direction of a portion of the second interconnection lines 232 corresponding to the second peripheral region 702.

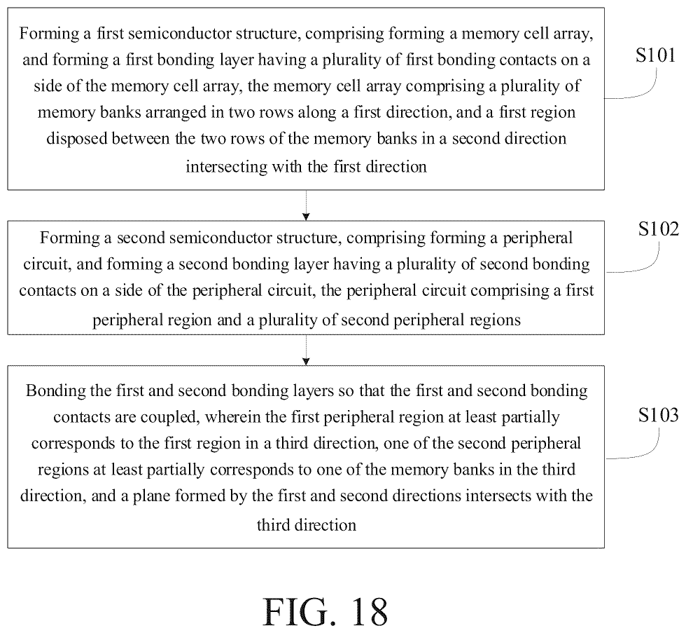

According to some aspects of the implementations of the present disclosure, FIG. 18 provides a method of manufacturing a memory apparatus. The method may include, e.g., operations S101, S102, and S103.

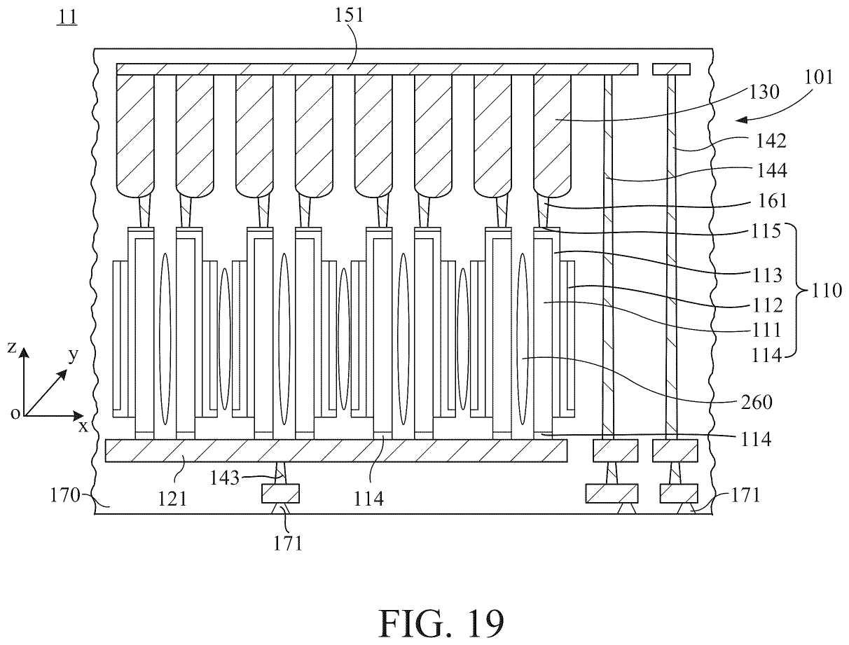

At S101, the method may include forming a first semiconductor structure 11 illustrated in FIG. 19. Forming the first semiconductor structure 11 may include forming a memory cell array 101, and forming a first bonding layer 170 having a plurality of first bonding contacts 171 on a side of the memory cell array 101, where the memory cell array 101 includes a plurality of memory banks 601 arranged based upon the example layout in FIG. 11, the plurality of memory banks 601 are arranged in two rows along the first direction (x-direction), and a first region 607 is disposed between the two rows of memory banks 601 in the second direction (y-direction) intersecting with the first direction;

At S102, the method may further include forming a second semiconductor structure 21 illustrated in FIG. 17. Forming a second semiconductor structure 21 may include forming a peripheral circuit 201, and forming a second bonding layer 220 having a plurality of second bonding contacts 221 on a side of the peripheral circuit 201, the peripheral circuit 201 including the first peripheral region 701 and the plurality of second peripheral regions 702 illustrated in FIG. 11.

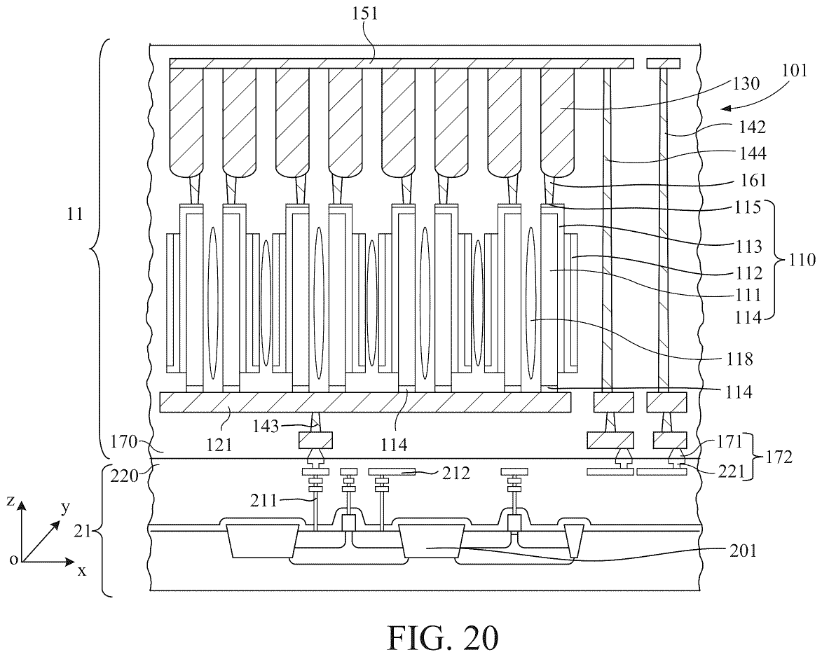

At S103, the method may further include bonding the first bonding layer 170 and the second bonding layer 220 so that the first bonding contacts 171 and the second bonding contacts 221 are coupled, as shown in FIG. 20. The first peripheral region 701 at least partially corresponds to the first region 607 in the third direction (z-direction), one of the second peripheral regions 702 at least partially corresponds to one of the memory banks 601 in the third direction, and the plane formed by the first direction and the second direction intersects with the third direction.

In some implementations, referring to FIG. 19, forming the memory cell array 101 includes forming a transistor 110. Forming the transistor 110 may include forming a first active region 114, a second active region 115, and a gate layer 112; forming a bit line 121 coupled to the first active region 114; and forming a capacitor structure 130 coupled to the second active region 115, where the peripheral circuit 201 is coupled to the bit line 121 through the first bonding contact 171 and the second bonding contact 221, and is coupled to the gate layer 112.

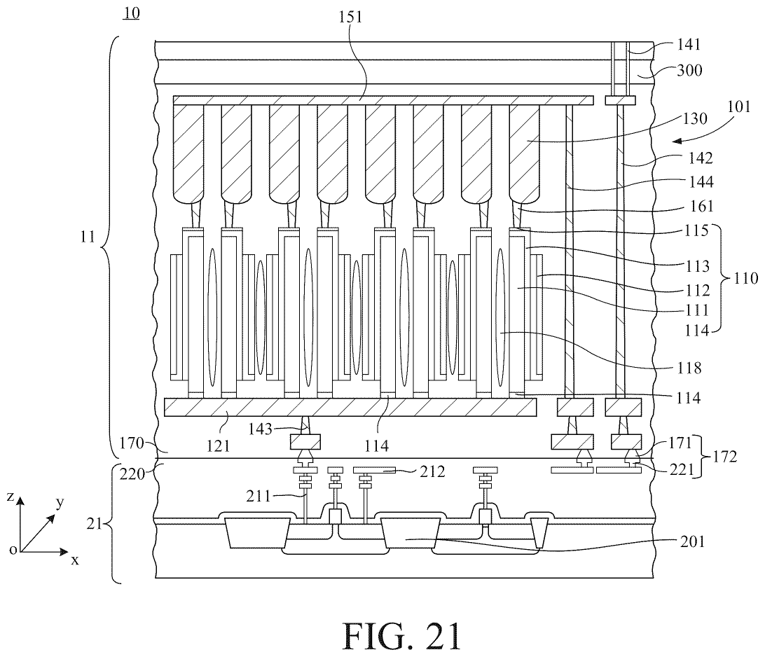

In some implementations, referring to FIG. 21, a material layer such as a semiconductor layer 300 is formed on a side of the first semiconductor structure 11 away from the capacitor structure 130. Alternatively, after the first semiconductor structure 11 is bonded to a semiconductor wafer or a substrate, and the semiconductor layer 300 is thinned from the back side thereof, a first connection structure 141 penetrating through the semiconductor layer 300 is formed, where the first connection structure 141 may include a TSV coupled to the first semiconductor structure 11 and the second semiconductor structure 21.

In some implementations, referring to FIG. 4, a pad 173 is formed on the first connection structure 141, where the pad 173 is coupled to the first connection structure 141, the pad 173 and the first connection structure 141 constitute a lead-out structure, and the pad 173 may serve as an I/O interface of the memory apparatus 10, which may supply power to the memory apparatus 10 and perform an external communication interaction.

In some implementations, referring to FIG. 15, forming the peripheral circuit 201 includes forming a first peripheral region 701. Forming the first peripheral region 701 may include forming at least a first data path circuit 711 in the first peripheral region 701, where the first data path circuit 711 is configured to transmit at least one of a control instruction, an address signal, or data.

In some implementations, forming the peripheral circuit 201 further includes forming a plurality of second peripheral regions 702 arranged at an interval along the x-direction on two sides of the first peripheral region 701 in the y-direction, as shown in FIG. 12. Forming the peripheral circuit 201 may include forming the plurality of second peripheral regions 702. Forming the plurality of second peripheral regions 702 may include forming in the second peripheral region 702 corresponding to a first memory bank, forming at least a word line driving circuit 812, a column decoding circuit 816, and a sensing amplification circuit 814 corresponding to the memory block 604 in the first memory bank, as illustrated in FIG. 8, where the first memory bank is one of the plurality of memory banks 601, such as the first memory bank bank15.

In some implementations, forming the peripheral circuit 201 further includes forming the memory bank column control circuit 602 illustrated in FIG. 6 between the second peripheral region 702 and the first peripheral region 701; and forming the memory bank row control circuit 603 illustrated in FIG. 6 between two adjacent second peripheral regions 702 in the x-direction.

In some implementations, referring to FIG. 14, the first peripheral region 701 includes a first sub-peripheral region 7011 located between adjacent second peripheral regions 702 in the y-direction, and a second sub-peripheral region 7012 located on a side of the first sub-peripheral region 7011 in the x-direction and located on a side of the two rows of second peripheral regions 702 in the x-direction.

In some implementations, forming the peripheral circuit 201 further includes forming a plurality of second data path circuits 712 on two sides of the first data path circuit 711 in the second direction, as shown in FIG. 12, where the second data path circuit 712 corresponds to the memory bank 601, and the second data path circuit 712 is coupled to the first data path circuit 711, as shown in FIG. 15.

In some implementations, forming the first data path circuit 711 includes forming the global transmission line 7111 and the local transmission line 7112, as shown in FIG. 15, where the second data path circuit 712 is coupled to the global transmission line 7111 through the local transmission line 7112.

In some implementations, forming the local transmission line 7112 includes forming control lines (local control lines 7113) and data transmission lines (local data transmission lines 7114) in different layers of the second semiconductor structure 21, as shown in FIG. 15.

In some implementations, manufacturing the second semiconductor structure 21 further includes forming a plurality of interconnection layers (for example, the CMOS M1 to CMOS TM shown in FIG. 3) stacked in the z-direction, where the plurality of interconnection layers are located between the peripheral circuit 201 and the second bonding contacts 221, and the peripheral circuit 201 is coupled to the second bonding contacts 221 through the plurality of interconnection layers.

In some implementations, referring to FIG. 16, the interconnection layers in the second semiconductor structure 21 may include a first interconnection layer (interconnection layer M2 or M4) and a second interconnection layer (interconnection layer M3 or TM) that are stacked, where the first interconnection layer includes a plurality of first interconnection lines 231 extending along a direction intersecting with the z-direction, the second interconnection layer includes a plurality of second interconnection lines 232 extending along a direction intersecting with the z-direction, and an extending direction of the first interconnection lines 231 intersects with an extending direction of the second interconnection lines 232; in a direction perpendicular to the z-direction, the first interconnection lines 231 are located between adjacent second bonding contacts 221; and in a direction perpendicular to the z-direction, the second interconnection lines 232 are located between adjacent second bonding contacts 221.

In some implementations, referring to FIG. 16, a portion (e.g., the portion being the local transmission line 7112) of the first interconnection lines 231 corresponding to the first peripheral region 701 intersects with an extending direction of a portion of the first interconnection lines 231 corresponding to the second peripheral region 702, and a portion (e.g., the portion being the global transmission line 7111) of the second interconnection lines 232 corresponding to the first peripheral region 701 intersects with an extending direction of a portion of the second interconnection lines 232 corresponding to the second peripheral region 702.

According to some aspects of implementations of the present disclosure, a memory system 902 is provided, including one or more memory apparatuses 10 as shown in FIGS. 4, 9, and 13-15; and a memory controller coupled to the memory apparatus 10 and controlling the memory apparatus 10.

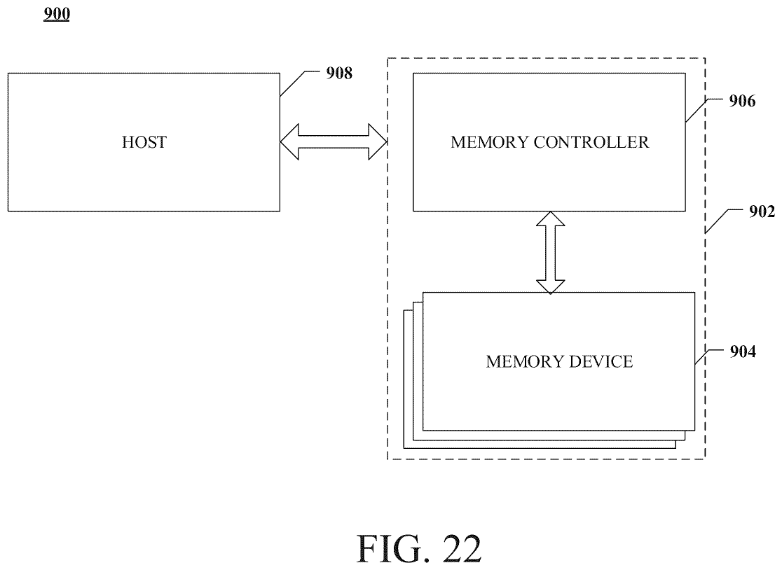

FIG. 22 provides a memory system 902 including a memory device 904 and a memory controller 906 coupled to the memory device 904, where the memory controller 906 controls the memory device 904, the memory device 904 includes the memory apparatus 10 shown in FIGS. 4, 9, 10, and 13-15, and the memory apparatus 10 includes the memory device 904 or at least a portion of the memory device 904.

Referring to FIG. 22, an implementation of the present disclosure provides a system 900 including a host 908. The system 900 may be a mobile phone, a graphics processing device, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a storage therein. As shown in FIG. 22, system 900 may include a host 908 and a memory system 902 having one or more memory devices 904 and a memory controller 906. The host 908 may be a processor of an electronic device (e.g., a central processing unit (CPU)) or a system-on-chip (SoC) (e.g., an application processor (AP)). The host 908 may be configured to send data to or receive data from the memory device 904, which may include the memory apparatus 10 of the present disclosure.

According to some implementations, the memory controller 906 is coupled to the memory device 904 and the host 908, and is configured to control the memory device 904 to perform read, write, or refresh. The memory controller 906 may manage data stored in the memory device 904 and communicate with the host 908. The memory device 904 may include a DRAM, or a package structure formed by stacking a plurality of DRAMs, and may be applied to an HBM (High Bandwidth Memory) or HMC (Hybrid Memory Cube) package structure.

In some example implementations, the HBM package structure may include a plurality of DRAM chips vertically stacked on the logic chip, where an electrical signal interconnection between the logic chip and the plurality of DRAM chips may be achieved through a through silicon via (TSV), and the plurality of DRAM chips and the logic chip may be configured as a memory system. The logic chip may include, but is not limited to, a control logic, an interface control module, an SRAM cache, or other components, the logic chip may be configured as the memory controller 906, and the memory apparatus 10 may be configured as the memory device 904 or the DRAM chip. The HBM package structure may further include a processor chip such as a GPU, a CPU, an SOC chip, or the like, where the memory controller may be integrated into the processor to control data transmission of the DRAM chip. For example, the processor such as a GPU or the like is coupled to the logic chip, and performs data interaction with the DRAM through the logic chip. In some other example implementations, the HMC (Hybrid Memory Cube) package structure may include a plurality of DRAM chips vertically stacked on the logic chip, where an electrical signal interconnection between the logic chip and the plurality of DRAM chips may be achieved through a TSV, and the plurality of DRAM chips and the logic chip may be configured as a memory system. The logic chip may include, but is not limited to, a control logic, an interface control module, an SRAM cache, or other components, and the memory controller may be integrated into the logic chip.

In some example implementations, the memory system 902 can be used as an auxiliary component in solid state drive, which can improve the reading and writing of the solid state drive. Some high-end solid state drive products often choose to embed DRAM to enhance product performance and improve random read and write speeds. For example, when writing files, especially small files, small files are first processed by DRAM and then stored in Flash, so that the solid state drive may have a higher storage efficiency and a faster speed. Flash may include non-volatile memory, including, but not limited to, 2D NAND memory or 3D NAND memory. In some examples, the memory system 902 may be used in a graphic processing device as a cache device of a graphic processing core (GPU). Here, the graphic processing device may include, but is not limited to, a graphic card.

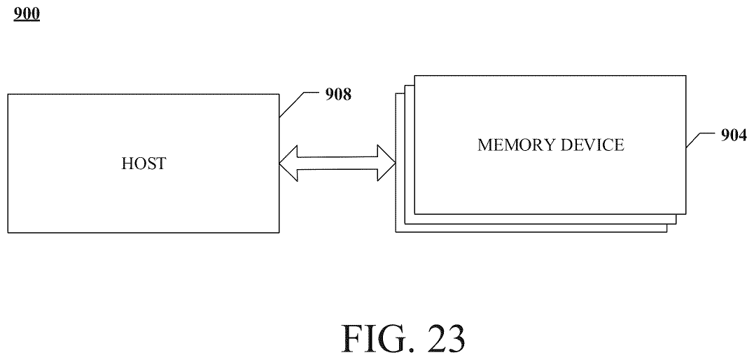

In some other implementations, referring to FIG. 23, the system 900 may include only the host 908 and the memory device 904 coupled to the host 908, and a controller for controlling the memory device 904 may be located inside the host 908; for example, the controller may include a memory controller integrated in a central processing unit (CPU), or a Southbridge or Northbridge chip integrated in the motherboard of the system 900. The memory device 904 may include, but is not limited to, a double data rate synchronous dynamic random access memory with a DDR4/DDR5 memory specification, and a low power consumption double data rate synchronous dynamic random access memory with a LPDDR5 memory specification. The memory device 904 may include the memory apparatus 10.

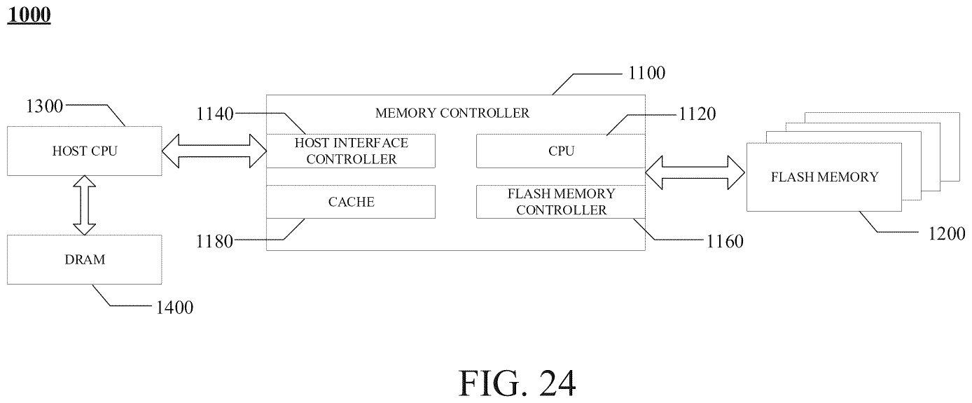

According to some aspects of implementations of the present disclosure, FIG. 24 provides a system 1000 (or electronic system) including a memory controller 1100, a host CPU 1300, and a flash memory 1200, the host CPU 1300 and the flash memory 1200 coupled to the memory controller 1100. The system 1000 may further include a memory device (DRAM 1400) coupled to the host CPU 1300. The memory controller 1100 may control the flash memory 1200. The flash memory 1200 may include a NADN memory, and the memory controller 1100 and the flash memory 1200 may constitute a memory system or a part of a memory system. The memory system may include, but is not limited to, a solid state drive (SSD), a memory card, or the like. The controller of the DRAM 1400 may be integrated into the host CPU 1300 as e.g., as a memory controller, or may be integrated into a Southbridge or Northbridge chip on a motherboard of the system 1000.

According to the implementations of the present disclosure, the memory device 904 in FIG. 23 may include the DRAM 1400 shown in FIG. 24, where the DRAM 1400 may include the memory apparatus 10 illustrated in FIG. 4, FIG. 9, FIG. 10, and FIG. 13 to FIG. 15 of the present disclosure. The controller for controlling the DRAM 1400 may be a memory controller integrated in the host CPU 1300 to control operations of the DRAM 1400, such as writing, reading, refreshing, or the like, and the host CPU 1300 may be coupled to the DRAM 1400 through a PCIe interface for performing data interaction. The memory controller 1100 and the flash memory 1200 may constitute a separate memory system, such as an SSD or a memory card, and the memory controller 1100 may include an SSD controller.

The memory controller 1100 may include a CPU 1120 (a control portion of the memory controller 1100), may receive a command from the host CPU 1300, and may control components such as a host interface controller 1140, a flash memory controller 1160, and a cache 1180 integrated in the memory controller 1100. The flash memory controller 1160 may control the back-end interface to perform data interaction with the flash memory 1200 to complete operations such as data encoding and decoding and ECC. The host interface controller 1140 controls the front-end interface to perform data interaction with the host CPU 1300, and the host interface controller 1140 may adapt to protocols such as SATA, PCIe, SAS, or the like. The cache 1180 may cache a portion of the logical address-physical address mapping table, and another portion of the logical address-physical address mapping table may be stored in the flash memory 1200, where the physical address is the physical address of the corresponding flash memory 1200. The cache 1180 may include, but is not limited to, static random access memory (SRAM), phase change memory (PCM), or the like. For example, the memory controller 1100 may perform data interaction with the host CPU 1300 through the DRAM 1400 with the DRAM 1400 used as a data mediator or a data buffer.

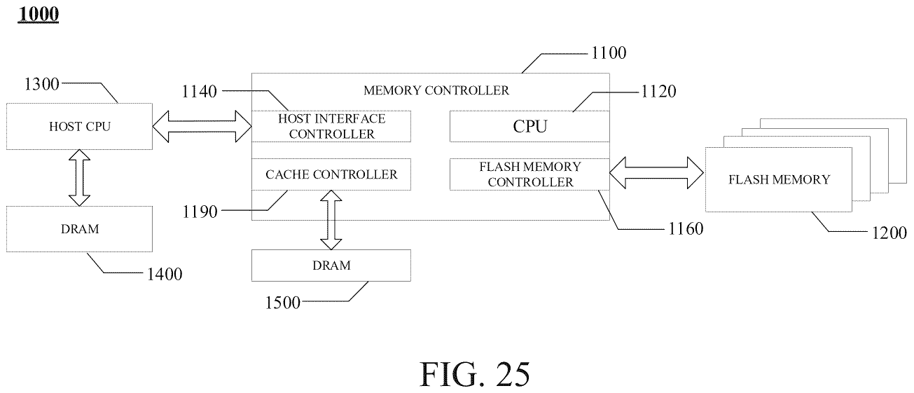

According to some aspects of implementations of the present disclosure, FIG. 25 provides a system 1000 including a memory controller 1100, a host CPU 1300, a flash memory 1200, and a memory device (DRAM 1500), the host CPU 1300, the flash memory 1200, and the memory device (DRAM 1500) coupled to the memory controller 1100. The system 1000 may further include a memory device (DRAM 1400) coupled to the host CPU 1300. The memory controller 1100 may include a cache controller 1190 to control the DRAM 1500. The memory controller 1100, the flash memory 1200, and the DRAM 1500 may constitute a memory system or a part of a memory system, which may include, but is not limited to, an SSD, a memory card, or the like. The memory system including the memory controller 1100, the flash memory 1200, and the DRAM 1500 may perform data interaction with the host CPU 1300 through the DRAM 1400 with the DRAM 1400 used as a data mediator or a data buffer. For example, the memory controller 1100 may perform data interaction with the host CPU 1300 through the DRAM 1400 with the DRAM 1400 used as a data mediator or a data buffer.

Referring to the system 1000 illustrated in FIG. 25, the memory controller 1100 may include a CPU 1120 (a control portion of the memory controller 1100), a host interface controller 1140, a flash memory controller 1160, and a cache controller 1190. The CPU 1120 may control the cache controller 1190 or receive data sent by the cache controller 1190. The cache controller 1190 may include a DRAM controller, control operations of the DRAM 1500, such as writing, reading, refreshing, or the like, and the DRAM 1500 may cache a logical address-physical address mapping table. The DRAM 1500 may include the memory apparatus 10 illustrated in FIGS. 4, 9, 10, and 13 through 15 of the present disclosure.

In some implementations provided by the present disclosure, it should be understood that the disclosed device and method may be implemented in a non-target manner. The device implementations described above are merely illustrative; for example, the division of the units is merely a logical function division, and in actual implementation, there may be another division manner. For example, multiple units or components may be combined, or may be integrated into another system, or some features may be omitted, or not included.

The above descriptions are only example implementations of the present disclosure, but the protection scope of the present disclosure is not limited thereto. Changes or replacements may be easily conceived by any person skilled in the art without departing from the technical scope of the present disclosure, and should be encompassed by the protection scope of the present disclosure.

What is claimed is:

1. A memory apparatus, comprising:
a first semiconductor structure comprising a memory cell array and a first bonding layer comprising first bonding contacts, wherein the memory cell array comprises memory banks arranged in two rows along a first direction, and there is a first region between two rows of the memory banks in a second direction intersecting with the first direction; and
a second semiconductor structure comprising a peripheral circuit and a second bonding layer having second bonding contacts, wherein the peripheral circuit comprises a first peripheral region and second peripheral regions, and a circuit of the first peripheral region is at least partially different from that of a second peripheral region of the second peripheral regions,
wherein the first bonding layer and the second bonding layer are bonded in a third direction, and the first bonding contacts and the second bonding contacts are coupled, wherein the first peripheral region at least partially corresponds to the first region in the third direction, one of the second peripheral regions at least partially corresponds to one of the memory banks in the third direction, and a plane formed by the first direction and the second direction intersects with the third direction.

2. The memory apparatus of claim 1, wherein:
the memory apparatus has two rows of the memory banks; and
one of the two rows of the memory banks comprises memory banks arranged along the first direction.

3. The memory apparatus of claim 1, wherein the first peripheral region at least partially overlaps the first region in the third direction, and one of the second peripheral regions at least partially overlaps one of the memory banks in the third direction.

4. The memory apparatus of claim 1, wherein the first peripheral region comprises at least a first data path circuit configured to transmit at least one of a control instruction, an address signal, or data.

5. The memory apparatus of claim 4, wherein:
the second peripheral regions are arranged at an interval in two rows along the first direction, and the two rows of the second peripheral regions are respectively located on two sides of the first peripheral region in the second direction;
a first memory bank of the memory banks comprises memory blocks; and
a second peripheral region corresponding to the first memory bank comprises at least a word line driving circuit, a column decoding circuit, and a sensing amplification circuit corresponding to the memory blocks in the first memory bank.

6. The memory apparatus of claim 5, wherein the peripheral circuit further comprises:
a memory bank column control circuit located between the second peripheral region and the first peripheral region; and
a memory bank row control circuit located between two adjacent ones of the second peripheral regions in the first direction.

7. The memory apparatus of claim 1, wherein the first peripheral region comprises:
a first sub-peripheral region located between adjacent ones of the second peripheral regions in the second direction; and
a second sub-peripheral region located on a side of the first sub-peripheral region in the first direction and located on a side of two rows of the second peripheral regions in the first direction.

8. The memory apparatus of claim 4, wherein the peripheral circuit further comprises:
second data path circuits located on two sides of the first data path circuit in the second direction, wherein the second data path circuit corresponds to the memory bank, and a second data path circuit of the second data path circuits is coupled to the first data path circuit;
wherein:
the first data path circuit comprises a global transmission line and a local transmission line;
the second data path circuit is coupled to the global transmission line through the local transmission line;
the local transmission line comprises a control line and a data transmission line; and
the control line and the data transmission line are in different interconnection layers in the third direction.

9. The memory apparatus of claim 1, wherein:
the second semiconductor structure comprises a interconnection layers stacked in the third direction;
the interconnection layers are located between the peripheral circuit and the second bonding contacts; and
the peripheral circuit is coupled to the second bonding contacts through the interconnection layers.

10. The memory apparatus of claim 9, wherein:
the interconnection layers in the second semiconductor structure comprise a first interconnection layer and a second interconnection layer that are stacked;
the first interconnection layer comprises a first interconnection lines extending in a direction intersecting with the third direction, the second interconnection layer comprises a second interconnection lines extending in a direction intersecting with the third direction, and an extending direction of the first interconnection lines intersects with an extending direction of the second interconnection lines;
in a direction perpendicular to the third direction, the first interconnection lines are located between adjacent ones of the second bonding contacts; and
in a direction perpendicular to the third direction, the second interconnection lines are located between adjacent ones of the second bonding contacts.

11. The memory apparatus of claim 10, wherein:
an extension direction of a portion of the first interconnection lines corresponding to the first peripheral region intersects with an extension direction of a portion of the first interconnection lines corresponding to the second peripheral region; and
an extending direction of a portion of the second interconnection lines corresponding to the first peripheral region intersects with an extension direction of a portion of the second interconnection lines corresponding to the second peripheral region.

12. The memory apparatus of claim 1, wherein the memory cell array comprises:
a transistor comprising a first active region, a second active region, and a gate layer;
a bit line coupled to the first active region; and
a capacitor structure coupled to the second active region,
wherein the peripheral circuit is coupled to the bit line through the first bonding contact and the second bonding contact, and is coupled to the gate layer.

13. A semiconductor structure, comprising:
a peripheral circuit, the peripheral circuit comprising:
a first peripheral region; and
second peripheral regions arranged at an interval in two rows along a first direction, the two rows of the second peripheral regions being respectively located on two sides of the first peripheral region in a second direction intersecting with the first direction,
wherein the first peripheral region comprises at least a first data path circuit configured to transmit at least one of a control instruction, an address signal, or data; and
wherein a second peripheral region of the second peripheral regions comprises at least word line driving circuits, column decoding circuits, and sensing amplification circuits.

14. The semiconductor structure of claim 13, further comprising:
a bonding layer having bonding contacts, wherein the bonding contacts are coupled to at least a portion of a region of the peripheral circuit.

15. The semiconductor structure of claim 13, wherein:
the peripheral circuit has two rows of the second peripheral regions; and
one of the two rows of the second peripheral regions comprises the second peripheral regions arranged along the first direction.

16. The semiconductor structure of claim 13, wherein the peripheral circuit further comprises:
a memory bank column control circuit located between the second peripheral region and the first peripheral region; and
a memory bank row control circuit located between two adjacent ones of the second peripheral regions in the first direction.

17. The semiconductor structure of claim 13, wherein the first peripheral region comprises:
a first sub-peripheral region located between adjacent ones of the second peripheral regions in the second direction, wherein at least a portion of the first data path circuit is located in the first sub-peripheral region; and
a second sub-peripheral region located on a side of the first sub-peripheral region in the first direction and located on a side of the two rows of the second peripheral regions in the first direction.

18. The semiconductor structure of claim 13, wherein:
the peripheral circuit further comprises second data path circuits located on two sides of the first data path circuit in the second direction; and
one of the second data path circuits corresponds to one of the second peripheral regions, and the second data path circuit is coupled to the first data path circuit;
wherein:
the first data path circuit comprises a global transmission line and a local transmission line;
the second data path circuit is coupled to the global transmission line through the local transmission line;
the local transmission line comprises a control line and a data transmission line;
the control line and the data transmission line are in different interconnection layers in a third direction; and
a plane formed by the first direction and the second direction intersects with the third direction.

19. The semiconductor structure of claim 14, further comprising:
interconnection layers stacked in a third direction, wherein the interconnection layers are located between the peripheral circuit and the bonding contacts, and the peripheral circuit is coupled to the bonding contacts through the interconnection layers;
wherein:
the interconnection layers in the semiconductor structure comprise a first interconnection layer and a second interconnection layer that are stacked;
the first interconnection layer comprises a first interconnection lines extending in a direction intersecting with the third direction, the second interconnection layer comprises a second interconnection lines extending in a direction intersecting with the third direction, and an extending direction of the first interconnection lines intersects with an extending direction of the second interconnection lines;
in a direction perpendicular to the third direction, the first interconnection lines are located between adjacent ones of the bonding contacts; and
in a direction perpendicular to the third direction, the second interconnection lines are located between adjacent ones of the bonding contacts.

20. A memory system, comprising:
one or more memory apparatuses, comprising:
a first semiconductor structure comprising a memory cell array and a first bonding layer comprising first bonding contacts, wherein the memory cell array comprises memory banks arranged in two rows along a first direction, and there is a first region between the two rows of the memory banks in a second direction intersecting with the first direction; and
a second semiconductor structure comprising a peripheral circuit and a second bonding layer having second bonding contacts, wherein the peripheral circuit comprises a first peripheral region and second peripheral regions, and a circuit of the first peripheral region is at least partially different from that of a second peripheral region of the second peripheral regions,
wherein the first bonding layer and the second bonding layer are bonded in a third direction, and the first bonding contacts and the second bonding contacts are coupled, wherein the first peripheral region at least partially corresponds to the first region in the third direction, one of the second peripheral regions at least partially corresponds to one of the memory banks in the third direction, and a plane formed by the first direction and the second direction intersects with the third direction; and
a memory controller coupled to the one or more memory apparatuses and controlling the one or more memory apparatuses.
